(19) United States
(12) Patent Application Publication
(10) Pub. No.: US 2026/0020227 A1
(43) Pub. Date: Jan. 15, 2026

(54) SEMICONDUCTOR MEMORY DEVICE

(71) Applicant: Samsung Electronics Co., Ltd., Suwon-si (KR)

(72) Inventors: Kyeongtae NAM, Suwon-si (KR); Chulkwon PARK, Suwon-si (KR)

(73) Assignee: Samsung Electronics Co., Ltd., Suwon-si (KR)

(21) Appl. No.: 19/029,156

(22) Filed: Jan. 17, 2025

(30) Foreign Application Priority Data
Jul. 9, 2024 (KR) 10-2024-0090103

(51) Int. Cl. H10B 12/00

(52) U.S. Cl. CPC H10B 12/482; H10B 12/03; H10B 12/05

(57) ABSTRACT

A semiconductor memory device includes a memory cell array, a plurality of global bitlines, a plurality of local bitlines, and a shielding structure. The memory cell array includes a plurality of memory cells on a semiconductor substrate. The plurality of global bitlines are above the memory cell array in a first direction perpendicular to a top surface of the semiconductor substrate, arranged in a second direction parallel to a top surface of the semiconductor substrate, and extend in a third direction parallel to a top surface of the semiconductor substrate. The plurality of local bitlines extend in the first direction and connect the plurality of memory cells and the plurality of global bitlines. The shielding structure is between the memory cell array and the plurality of global bitlines and is configured to at least partly shield electrical interference between the memory cell array and the plurality of global bitlines.

### CROSS-REFERENCE TO RELATED APPLICATION

This U.S. non-provisional application claims priority under 35 USC § 119 to Korean Patent Application No. 10-2024-0090103, filed on Jul. 9, 2024, in the Korean Intellectual Property Office (KIPO), the disclosure of which is incorporated by reference herein in its entirety.

### BACKGROUND

Some example embodiments relate generally to semiconductor integrated circuits, and more particularly to a semiconductor memory device in which memory cells are stacked in a vertical direction.

Recently, the electronics market has seen a rapid increase in the demand for portable devices, which has led to a continuous desire for miniaturization and/or for lightweight of components such as semiconductor memory devices mounted in the electronic devices. To help realize miniaturization and lightweight of the semiconductor memory devices, not only technologies of reducing the individual size of mounting components are expected, but also technologies of reducing degradation of electrical characteristics due to miniaturization and lightweight. In particular, semiconductor memory devices with high operation speed expect excellent electrical characteristics in addition to miniaturization.

### SUMMARY

Some example embodiments may provide semiconductor memory devices having enhanced electrical characteristics.

According to some example embodiments, a semiconductor memory device includes a memory cell array, a plurality of global bitlines, a plurality of local bitlines, and a shielding structure. The memory cell array includes a plurality of memory cells on a semiconductor substrate. The plurality of global bitlines are above the memory cell array in a first direction perpendicular to a top surface of the semiconductor substrate, arranged in a second direction parallel to a top surface of the semiconductor substrate, and extend in a third direction parallel to a top surface of the semiconductor substrate. The plurality of local bitlines extend in the first direction and connect the plurality of memory cells and the plurality of global bitlines. The shielding structure is between the memory cell array and the plurality of global bitlines, and is configured to at least partially shield electrical interference between the memory cell array and the plurality of global bitlines.

Alternatively or additionally according to some example embodiments, a semiconductor memory device includes a first semiconductor die, and a second semiconductor die stacked on the first semiconductor die in a first direction perpendicular to the semiconductor substrate. The first semiconductor die includes a memory cell array including a plurality of memory cells on a semiconductor substrate, a plurality of global bitlines above the memory cell array in a first direction perpendicular to a top surface of the semiconductor substrate, arranged in a second direction parallel to a top surface of the semiconductor substrate, and extending in a third direction parallel to a top surface of the semiconductor substrate, a plurality of local bitlines extending in the first direction and connecting the plurality of memory cells and the plurality of global bitlines, and a shielding structure between the memory cell array and the plurality of global bitlines and configured to at least partly shield electrical interference between the memory cell array and the plurality of global bitlines. The second semiconductor die includes a sense amplifier circuit configured to sense data stored in select memory cells from among the plurality of memory cells based on voltages of the plurality of global bitlines.

Alternatively or additionally according to some example embodiments, a semiconductor memory device includes a memory cell array including a plurality of dynamic random access memory (DRAM) cells memory cells on a semiconductor substrate, wherein the plurality of DRAM cells are arranged in a plurality of cell layers spaced apart and stacked in a first direction perpendicular to a top surface of the semiconductor substrate, and DRAM cells in each cell layer of the plurality of cell layers are arranged in the second direction and the third direction, a plurality of global bitlines above the memory cell array in the first direction, arranged in a second direction parallel to a top surface of the semiconductor substrate, and extending in a third direction parallel to a top surface of the semiconductor substrate, a plurality of local bitlines extending in the first direction, arranged in the second direction and the third direction, and connecting the plurality of memory cells and the plurality of global bitlines, and a shielding conductive plate between the memory cell array and the plurality of global bitlines, the shielding conductive layer configured to at least partly shield electrical interference between the memory cell array and the plurality of global bitlines, wherein shielding conductive plate is parallel to the top surface of the semiconductor die to cover the memory cell array.

The semiconductor memory device according to some example embodiments may have improved performance by reducing electrical interference between the global bitlines and the memory cell array using the shielding structure. Shielding between the global bitlines and the capacitor electrode of the memory cell using the shielding structure may improve the electrical performance of the semiconductor memory device by reducing the coupling or coupling capacitance between the global bitlines and the capacitor electrode and/or by increasing the capacitance of the capacitor electrode to stabilize the voltage of the capacitor electrode.

### BRIEF DESCRIPTION OF THE DRAWINGS

Some example embodiments will be more clearly understood from the following detailed description taken in conjunction with the accompanying drawings.

FIG. 1 is a perspective diagram illustrating a semiconductor memory device according to some example embodiments.

FIG. 2 is a vertical cross-sectional diagram illustrating the semiconductor memory device of FIG. 1 viewed from a second direction.

FIG. 3 is a vertical cross-sectional diagram illustrating the semiconductor memory device of FIG. 1 viewed from a third direction.

FIG. 4 is a perspective diagram illustrating an example embodiment of a shielding structure in a semiconductor memory device according to some example embodiments.

FIG. 5 is a vertical cross-sectional diagram illustrating the semiconductor memory device of FIG. 4 viewed from a second direction.

FIG. 6 is a perspective diagram illustrating an example embodiment of a shielding structure in a semiconductor memory device according to some example embodiments.

FIG. 7 is a vertical cross-sectional diagram illustrating the semiconductor memory device of FIG. 6 viewed from a second direction.

FIG. 8 is a block diagram illustrating a semiconductor memory device according to some example embodiments.

FIG. 9 is a vertical cross-sectional diagram illustrating a semiconductor memory device according to some example embodiments.

FIG. 10 is a perspective diagram illustrating an example embodiment of a cell layer in the semiconductor memory device of FIG. 9.

FIG. 11 is a vertical cross-sectional diagram illustrating a semiconductor memory device according to some example embodiments.

FIG. 12 is a perspective diagram illustrating an example embodiment of a cell layer in the semiconductor memory device of FIG. 11.

FIG. 13 is a diagram illustrating a semiconductor memory device according to some example embodiments.

FIG. 14 is a diagram illustrating an example embodiment of a switch circuit in the semiconductor memory device of FIG. 13.

FIG. 15 is a diagram illustrating a manufacturing process of the semiconductor memory device of FIG. 13.

FIGS. 16, 17 and 18 are a plan view and cross-sectional views illustrating a semiconductor memory device according to some example embodiments.

FIGS. 19 through 46 are plan views and cross-sectional views illustrating example embodiments of manufacturing a semiconductor memory device according to some example embodiments.

FIG. 47 is a diagram illustrating a semiconductor memory device according to some example embodiments.

FIG. 48 is a diagram illustrating a semiconductor package including semiconductor memory devices according to some example embodiments.

FIG. 49 is a block diagram illustrating a mobile system including a semiconductor memory device according to some example embodiments.

### DETAILED DESCRIPTION OF SOME EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

As described herein, a direction perpendicular to a top surface of a semiconductor substrate is defined as a first direction D1, and two directions parallel to the top surface of the semiconductor substrate and intersecting each other are defined as a second direction D2 and a third direction D2. For example, the second direction D2 and the third direction D3 may intersect substantially perpendicular to each other. The first direction D1 may also be referred to as a vertical direction, the second direction D2 as a first horizontal direction or a row direction, and the third direction D3 as a second horizontal direction or a column direction. The first direction D1, the second direction D2, and the third direction D3 refer to the directions indicated by the arrows in the drawings or the opposite directions of the first direction D1, the second direction D2, and the third direction D3, respectively. The definitions of the aforementioned directions are the same in all subsequent drawings.

As described herein, the number of memory cells, the number of cell layers, the number of global bitlines, the number of local bitlines, and the like are for convenience of illustration and description and are not limited to any particular number.

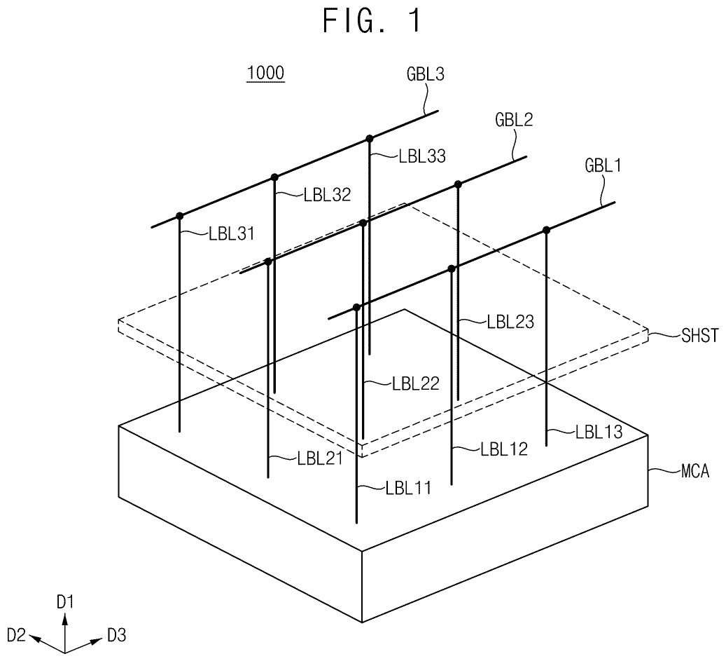

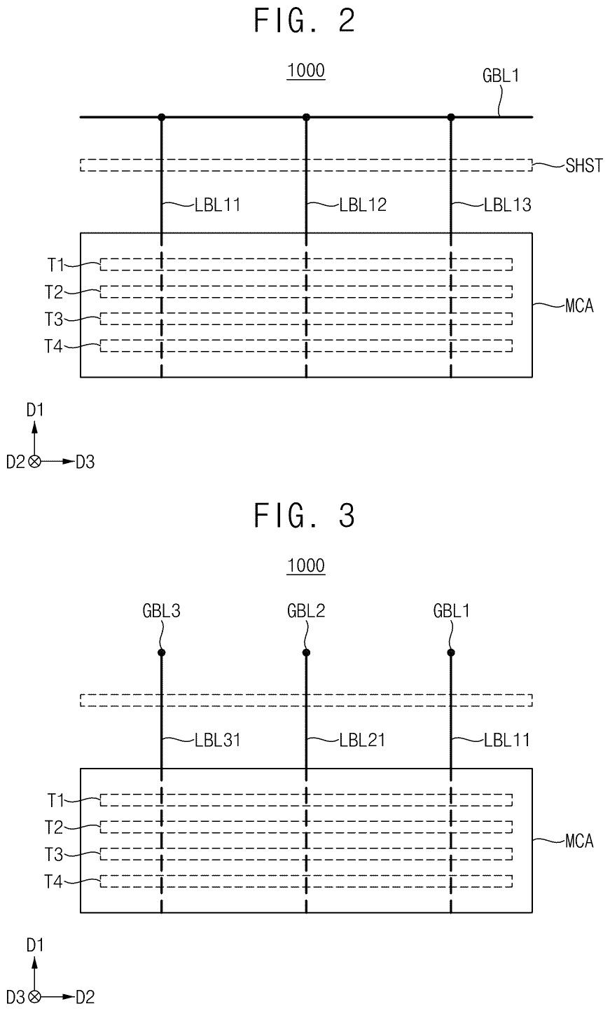

FIG. 1 is a perspective diagram illustrating a semiconductor memory device according to some example embodiments. FIG. 2 is a vertical cross-sectional diagram illustrating the semiconductor memory device of FIG. 1 viewed from a second direction, and FIG. 3 is a vertical cross-sectional diagram illustrating the semiconductor memory device of FIG. 1 viewed from a third direction.

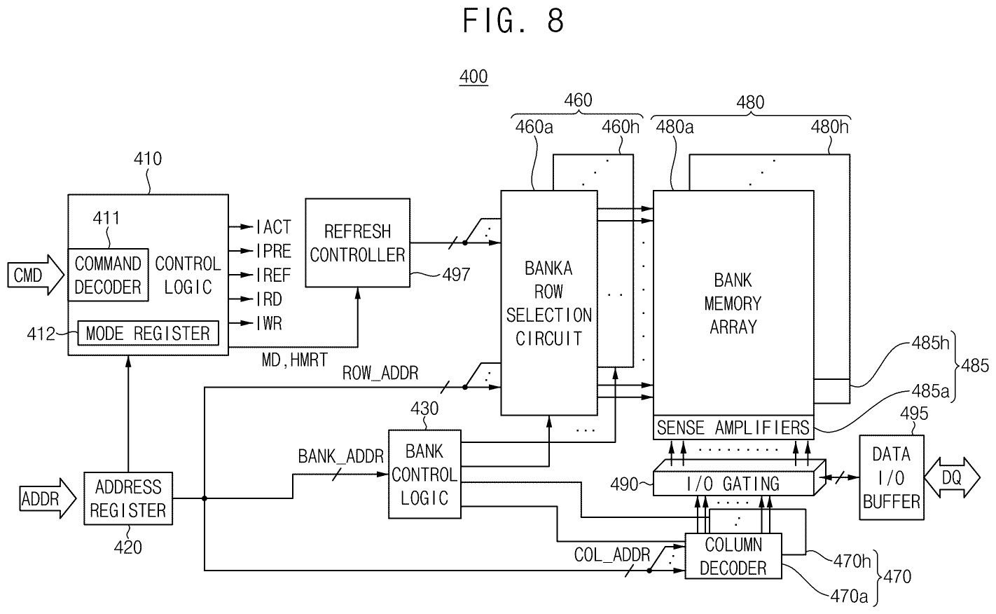

Referring to FIGS. 1, 2 and 3, a semiconductor memory device 1000 may include a memory cell array MCA, a plurality of global bitlines GBL1 through GBL3, a plurality of local bitlines LBL11 through LBL33, and a shielding structure SHST. FIGS. 1 through 3 illustrate only components to describe some example embodiments, and the semiconductor memory device 1000 may further include various other components as will be further described below with reference to FIG. 8.

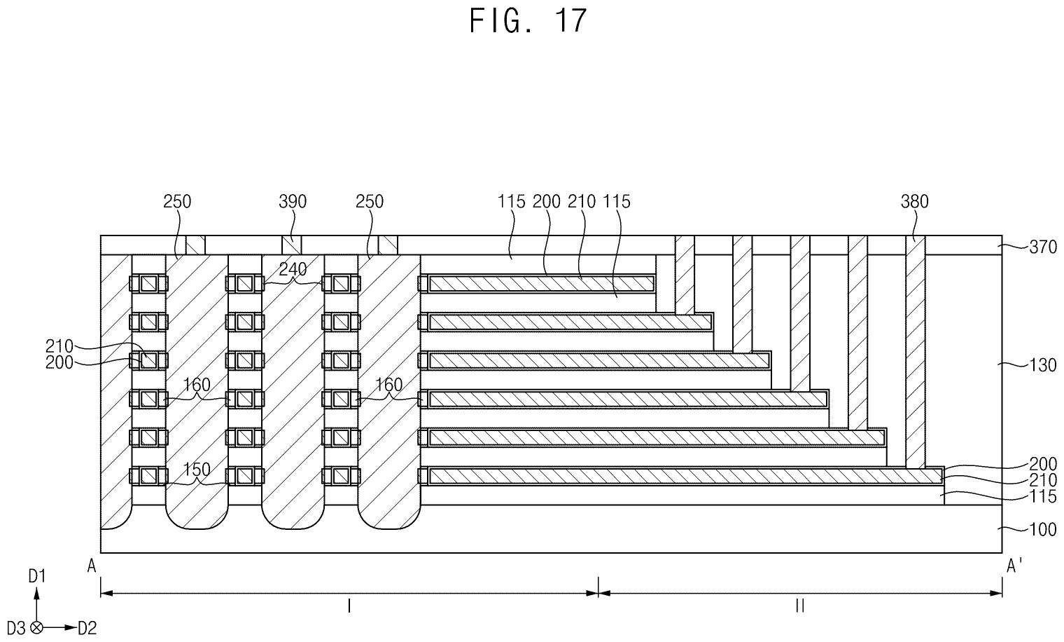

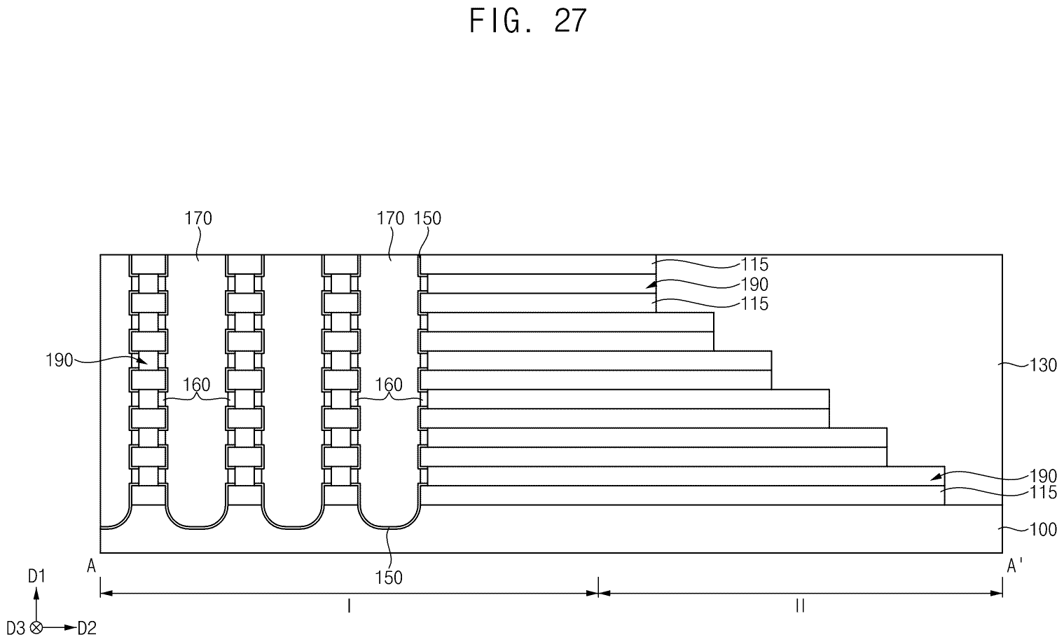

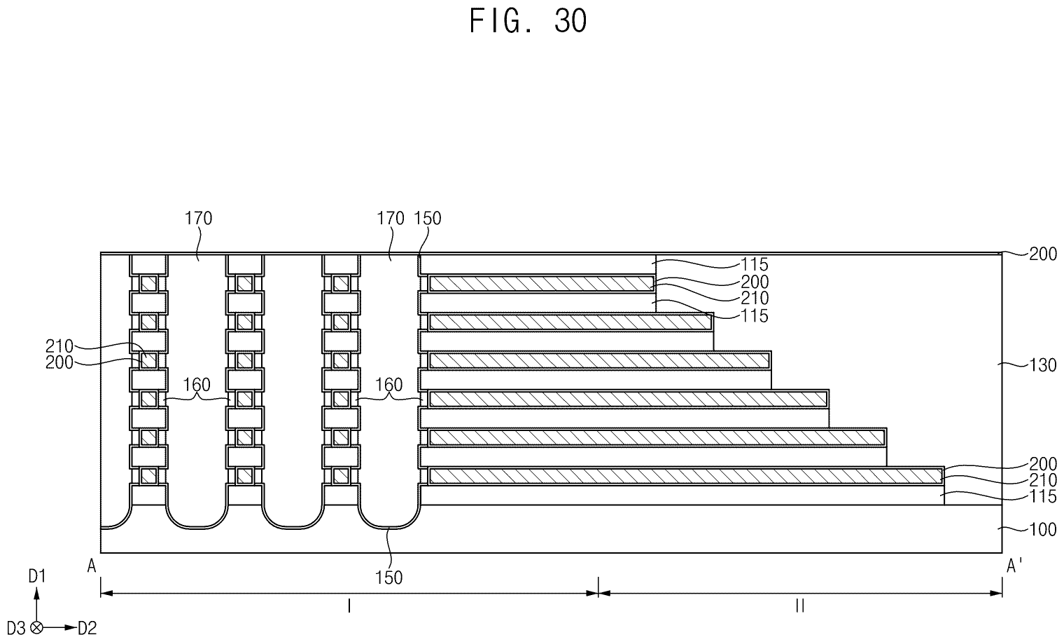

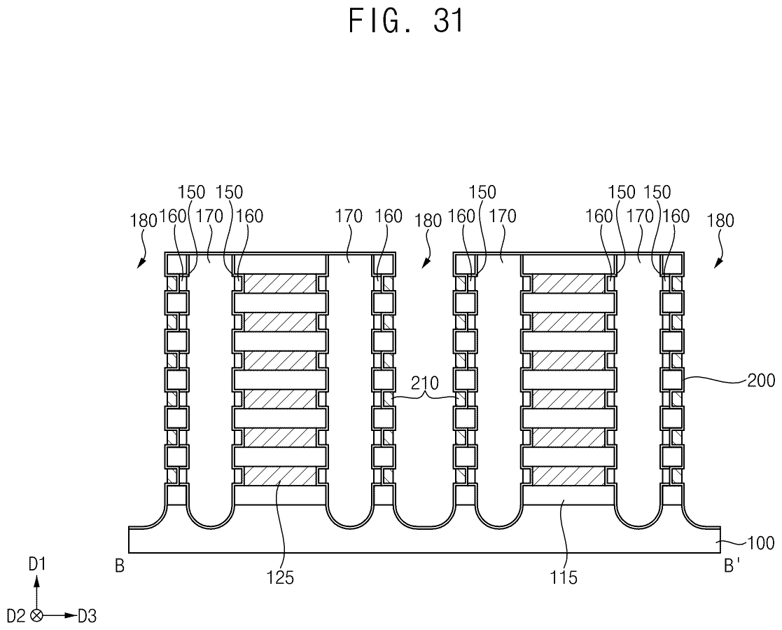

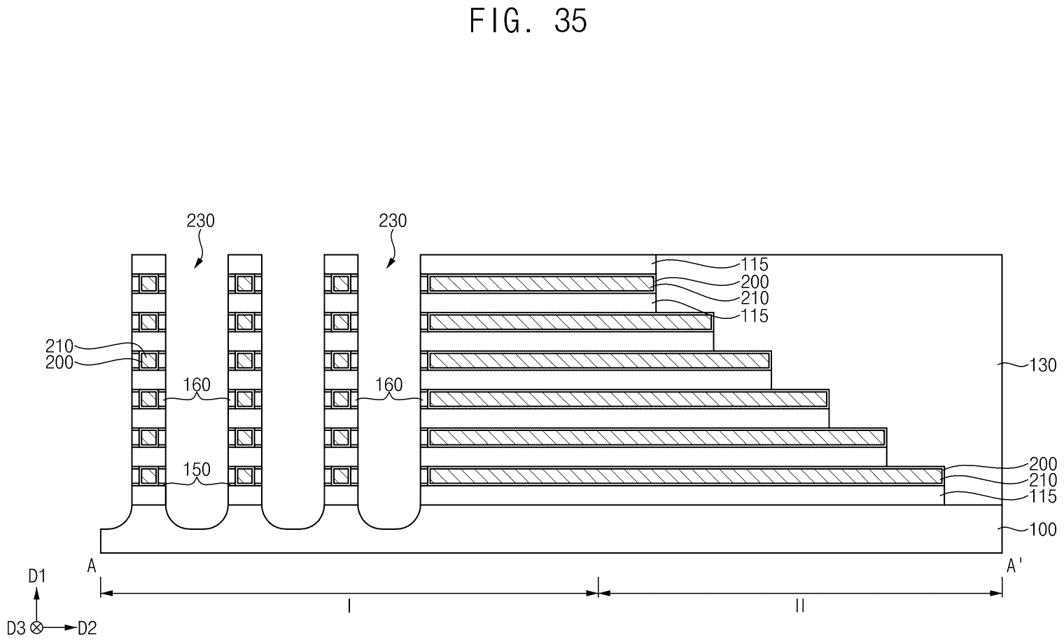

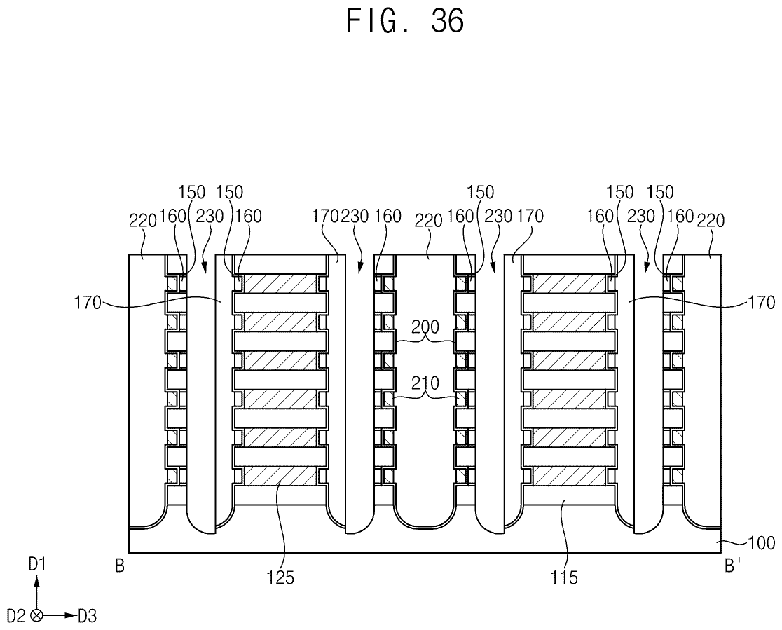

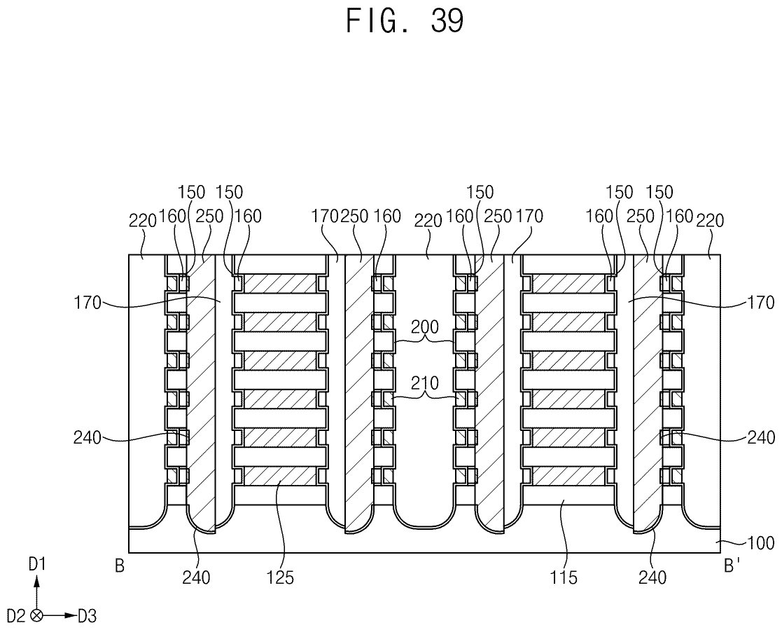

The plurality of global bitlines GLB1 through GLB3 are disposed above the memory cell array MCA in a first direction D1 perpendicular to a top surface of a semiconductor substrate (e.g., the semiconductor substrate 100 of FIGS. 16 through 46). Further, the plurality of global bitlines GLB1 through GLB3 are arranged in a second direction D2 parallel to the top surface of the semiconductor substrate and extend in a third direction D3 parallel to the top surface of the semiconductor substrate. The plurality of global bitlines GLB1 through GLB3 may be arranged at a constant pitch or spacing in the second direct D2; however, example embodiments are not limited thereto.

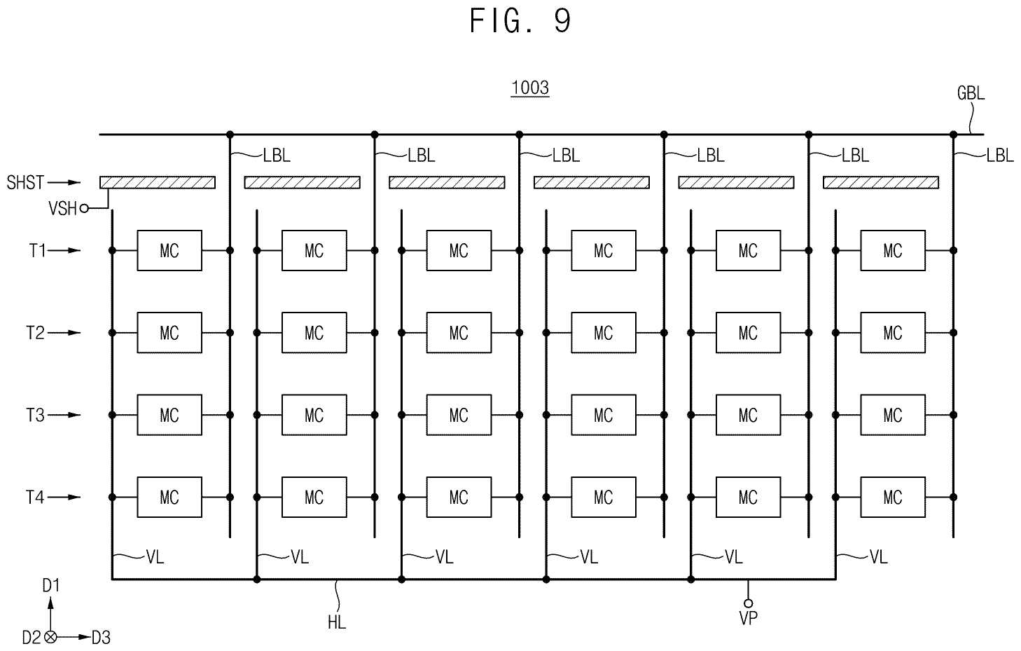

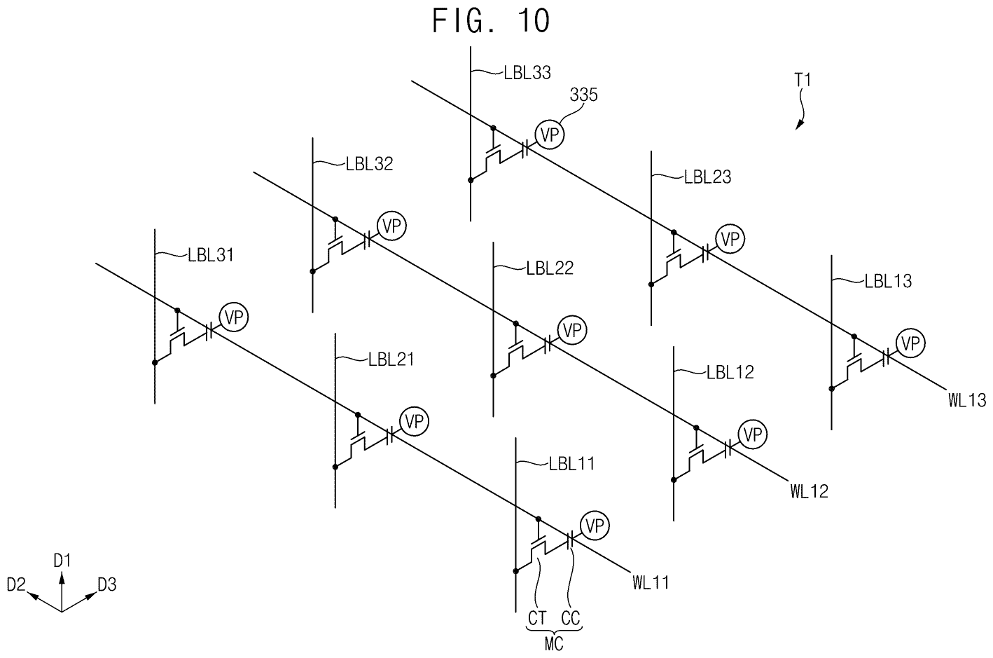

The plurality of local bitlines LBL11 through LBL33 extend in the first direction D1 to connect the plurality of memory cells included in the memory cell array MCA and the plurality of global bitlines GBL1 through GBL3. Example embodiments of connections between the plurality of local bitlines LBL11 through LBL33 and the plurality of memory cells are further described below with reference to FIGS. 9 through 12 and FIGS. 16 through 46.

Some of the plurality of local bitlines LBL11 through LBL33 may be arranged at a first constant pitch or spacing in the second direction D2 and some of the plurality of local bitlines LBL11 through LBL33 may be arranged in a constant pitch or spacing in the third direction D3; however, example embodiments are not limited thereto. For example, a pitch between local bitlines LBL11, LBL12, and LBL13 in the third direction D3 may be the same as, or different from, a pitch between local bitlines LBL11, LBL21, and LBL31 in the second direction D2, which, in some example embodiments, may be the same as the pitch between global bitlines GBL1, GBL2, and GBL3 in the second direction D2.

As shown in FIGS. 2 and 3, the plurality of memory cells may form or be arranged in a plurality of cell layers T1 through T4 that are stacked spaced apart in a first direction D1. As will be described below with reference to FIGS. 9 through 12, in each cell layer of the plurality of cell layers T1 through T4, the memory cells may be arranged in the second direction D2 and the third direction D3, and the plurality of local bitlines LBL11 through LBL33 may be arranged in the second direction D2 and the third direction D3. In this case, the local bitlines LBL11 through LBL13 of the first group arranged in the third direction D3 are connected to the corresponding first global bitline GBL1, the local bitlines LBL21 through LBL23 of the second group arranged in the third direction D3 are connected to the corresponding second global bitline GBL2, and the local bitlines LBL31 through LBL33 of the third group arranged in the third direction D3 are connected to the corresponding third global bitline GBL3.

FIGS. 1 through 3 illustrate, but are not limited to, a local bitline being directly connected to a global bitline. In some example embodiments, the local bitlines may be connected to the global bitlines via contact plugs 380 as will be further described below with reference to FIGS. 16 through 46, in which case the contact plugs 380 may be considered a portion of the local bitlines.

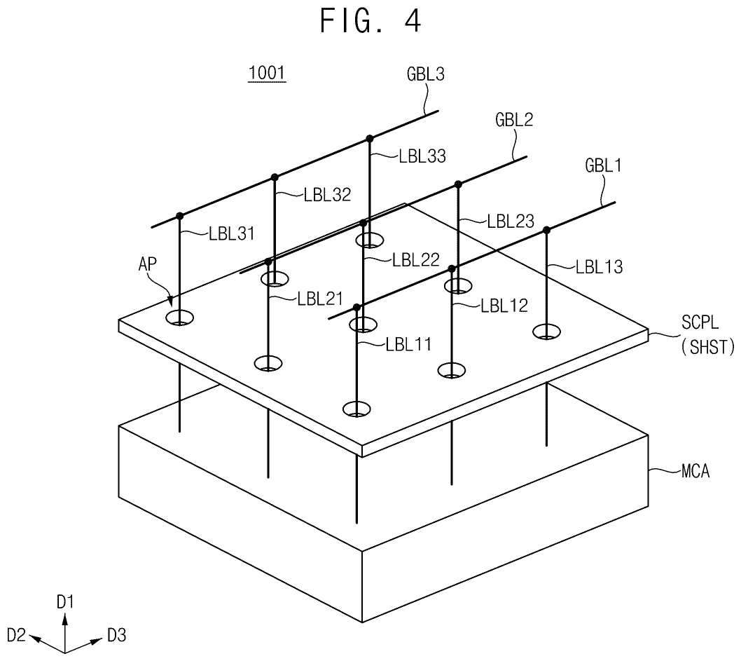

The shielding structure SHST is formed between the memory cell array MCA and the plurality of global bitlines GBL1 through GBL3 to shield or at least partly shield electrical interference between the memory cell array MCA and the plurality of global bitlines GBL1 through GBL3. For example, the memory cell array MCA, the shielding structure SHST, and the global bitlines GBL1 through GBL3 may be sequentially disposed in the first direction D1. Example embodiments of the shielding structure SHST will be further described below with reference to FIGS. 4 through 7.

The semiconductor memory device 1000 according to some example embodiments may have improved performance by reducing electrical interference between the global bitlines GBL1 through GBL3 and the memory cell array MCA by utilizing the shielding structure SHST.

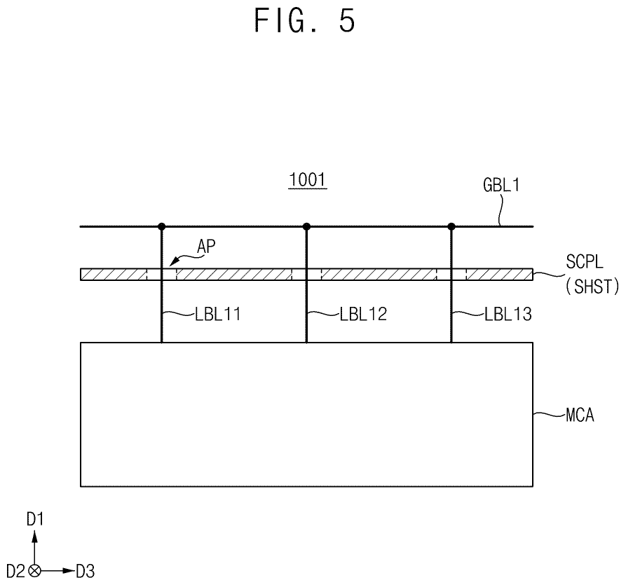

FIG. 4 is a perspective diagram illustrating an example embodiment of a shielding structure in a semiconductor memory device according to some example embodiments, and FIG. 5 is a vertical cross-sectional diagram illustrating the semiconductor memory device of FIG. 4 viewed from a second direction. Hereinafter, repeated descriptions with FIGS. 1 through 3 may be omitted.

Referring to FIGS. 4 and 5, a semiconductor memory device 1001 may include a memory cell array MCA, a plurality of global bitlines GBL1 through GBL3, a plurality of local bitlines LBL11 through LBL33, and a shielding structure SHST. Hereinafter, description that is redundant with FIGS. 1 through 3 may be omitted.

The shielding structure SHST may include a shielding conductive plate SCPL. The shielding conductive plate SCPL may have a plate shape disposed parallel to the top surface of the semiconductor die, e.g., perpendicular to the first direction D1, to cover the memory cell array MCA.

As shown in FIGS. 4 and 5, a plurality of apertures AP may be formed in the shielding conductive plate SCPL. The plurality of local bitlines LBL11 through LBL33 may extend in the first direction D1 through the plurality of apertures AP not to contact the shielding conductive plate SCPL, e.g., not to be electrically connected to the shielding conductive plate SCPL, and may be connected to the plurality of global bitlines GBL1 through GBL3.

The plurality of apertures AP may be arranged to correspond to an array structure of the plurality of local bitlines LBL11 through LBL12. In some example embodiments, the plurality of local bitlines LBL11 through LBL33 may be arranged in the second direction D2 and the third direction D3. In this case, the plurality of apertures AP may be arranged in the second direction D2 and the third direction D3 to correspond to the array structure of the plurality of local bitlines LBL11 through LBL12. Each local bitline LBLij (wherein i=1,2 or 3, and j=1,2 or 3) may be connected to a corresponding global bitline GBLi through a corresponding aperture AP.

The plurality of apertures AP may be formed via an etching process, e.g., a wet and/or dry etching process, after the shielding conductive plate SCPL is formed. According to some example embodiments, after the plurality of apertures APs are formed, an etching process may be performed to form the local bitlines LBL11 through LBL13 or the contact plugs 380 of FIGS. 16 through 46.

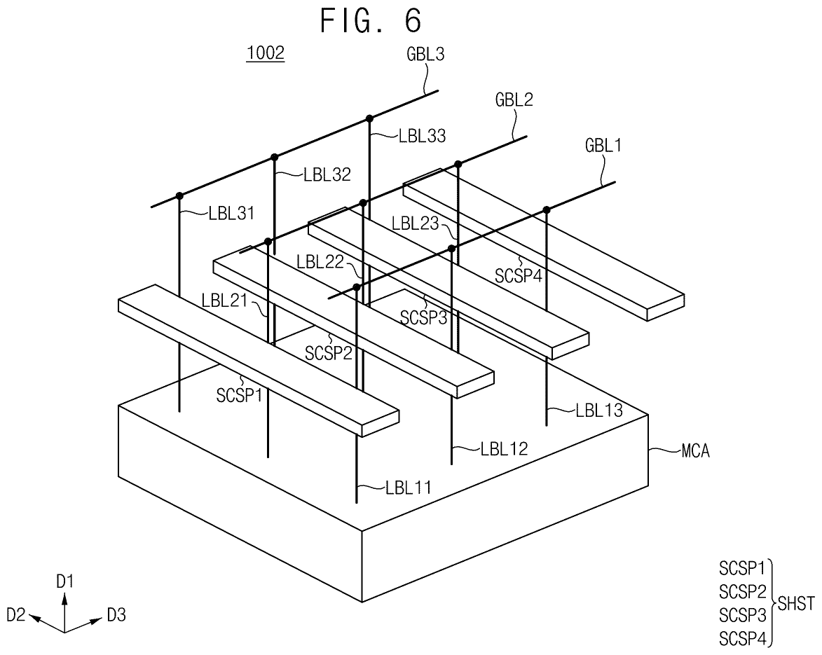

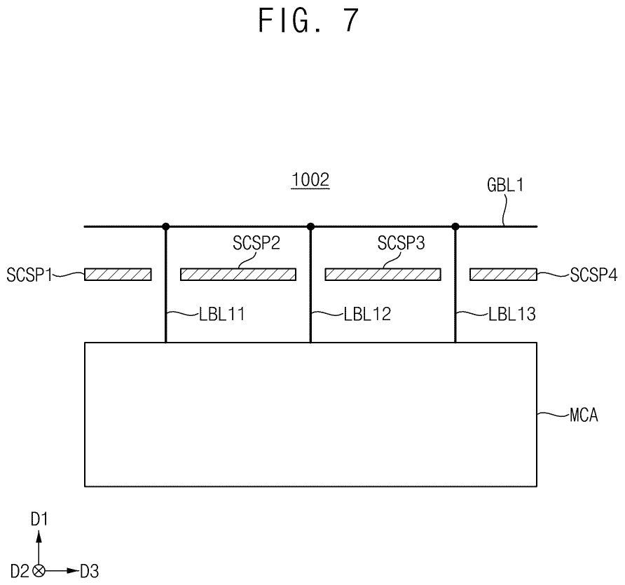

FIG. 6 is a perspective diagram illustrating some example embodiments of a shielding structure in a semiconductor memory device according to some example embodiments, and FIG. 7 is a vertical cross-sectional diagram illustrating the semiconductor memory device of FIG. 6 viewed from a second direction.

Referring to FIGS. 6 and 7, a semiconductor memory device 1002 may include a memory cell array MCA, a plurality of global bitlines GBL1 through GBL3, a plurality of local bitlines LBL11 through LBL33, and a shielding structure SHST. Hereinafter, repeated descriptions with FIGS. 1 through 3 may be omitted.

The shielding structure SHST may include a plurality of shielding conductive stripes SCSP1 through SCSP4. The plurality of shielding conductive stripes SCSP1 through SCSP4 may be formed parallel to the top surface of the semiconductor die, extend in the second direction D2, and arranged in the third direction D3 to cover portions of the memory cell array MAC that are not traversed by the plurality of local bitlines LBL11 through LBL33. A width, e.g., a width in the D3 direction, and/or a spacing, e.g., a spacing in the D3 direction, of each of the plurality of shielding constructive strips SCSP1 through SCSP4 may be constant; however, example embodiments are not limited thereto.

As shown in FIGS. 6 and 7, the plurality of local bitlines LBL11 through LBL33 may be connected to the plurality of global bitlines GBL1 through GBL3 by passing between the plurality of shielding conductive stripes SCSP1 through SCSP4 and extending in the first direction D1 not to contact the plurality of shielding conductive stripes SCSP1 through SCSP4.

In some example embodiments, the plurality of shielding conductive stripes SCSP1 through SCSP4 may be electrically connected to each other via conductive lines (not shown) extending in the third direction D3. In some example embodiments, the plurality of shielding conductive strips SCSP1 through SCSP4 may be connected as a comb structure and/or as a snake structure; example embodiments are not limited thereto.

The plurality of shielding conductive stripes SCSP1 through SCSP4 may be formed via a metal patterning process. According to some example embodiments, after the plurality of shielding conductive stripes SCSP1 through SCSP4 are formed, an etching process such as a wet and/or dry etching process may be performed to form the local bitlines LBL11 through LBL13 or the contact plugs 380 of FIGS. 16 through 46.

FIG. 8 is a block diagram illustrating a semiconductor memory device according to some example embodiments.

Referring to FIG. 8, a semiconductor memory device 400 may include a command control logic 410, an address register 420, a bank control logic 430, a row selection circuit 460 (or row decoder), a column decoder 470, a memory cell array 480, a sense amplifier unit 485, an input-output (I/O) gating circuit 490, a data input-output (I/O) buffer 495, and a refresh controller 497.

The memory cell array 480 may include a plurality of bank arrays 480a, . . . , 480h. The row selection circuit 460 may include a plurality of bank row selection circuits 460a, . . . , 460h respectively coupled to the bank arrays 480a, . . . , 480h. The column decoder 470 may include a plurality of bank column decoders 470a, . . . , 470h respectively coupled to the bank arrays 480a, . . . , 480h. The sense amplifier unit 485 may include a plurality of bank sense amplifiers 485a, . . . , 485h respectively coupled to the bank arrays 480a, . . . , 480h. A number of columns in the memory cell array 480 may be the same as, or different from (e.g., greater than or less than) a number of rows in the memory cell array 480.

As described with reference to FIGS. 1 through 7, the shielding structure SHST may be disposed above the memory cell array 480 and the plurality of local bit lines may be formed above the shielding structure SHST.

The address register 420 may receive an address ADDR including a bank address BANK_ADDR, a row address ROW_ADDR, and a column address COL_ADDR from the memory controller 50. The address register 420 may provide the received bank address BANK_ADDR to the bank control logic 430, may provide the received row address ROW_ADDR to the row selection circuit 460, and may provide the received column address COL_ADDR to the column decoder 470.

The bank control logic 430 may generate bank control signals in response to the bank address BANK_ADDR. One of the bank row selection circuits 460a, . . . , 460h corresponding to the bank address BANK_ADDR may be activated in response to the bank control signals, and one of the bank column decoders 470a, . . . , 470h corresponding to the bank address BANK_ADDR may be activated in response to the bank control signals.

The row address ROW_ADDR from the address register 420 may be applied to the bank row selection circuits 460a, . . . , 460h. The activated one of the bank row selection circuits 460a, . . . , 460h may decode the row address ROW_ADDR, and may activate a wordline corresponding to the row address ROW_ADDR. For example, the activated bank row selection circuit 460 may apply a wordline driving voltage to the wordline corresponding to the row address ROW_ADDR.

The column decoder 470 may include a column address latch. The column address latch may receive the column address COL_ADDR from the address register 420, and may temporarily store the received column address COL_ADDR. In some example embodiments, in a burst mode, the column address latch may generate column addresses that increment from the received column address COL_ADDR. The column address latch may apply the temporarily stored or generated column address to the bank column decoders 470a, . . . , 470h.

The activated one of the bank column decoders 470a, . . . , 470h may decode the column address COL_ADDR, and may control the I/O gating circuit 490 in order to output data corresponding to the column address COL_ADDR.

The I/O gating circuit 490 may include a circuitry for gating input-output data. The I/O gating circuit 490 may further include read data latches for storing data that is output from the bank arrays 480a, . . . , 480h, and write drivers for writing data to the bank arrays 480a, . . . 480h.

Data to be read from one bank array of the bank arrays 480a, . . . , 480h may be sensed by one of the bank sense amplifiers 485a, . . . , 485h coupled to the one bank array from which the data is to be read, and may be stored in the read data latches. The data stored in the read data latches may be provided to the memory controller 50 via the data I/O buffer 495. Data DQ to be written in one bank array of the bank arrays 480a, . . . , 480h may be provided to the data I/O buffer 495 from the memory controller 50. The write driver may write the data DQ in one bank array of the bank arrays 480a, . . . , 480h.

The command control logic 410 may control some or all operations of the semiconductor memory device 400. For example, the command control logic 410 may generate control signals for the semiconductor memory device 400 in order to perform one or more of a write operation, a read operation, or a refresh operation. The command control logic 410 may generate internal command signals such as an active signal IACT, a precharge signal IPRE, a refresh signal IREF, a read signal IRD, a write signal IWR, etc., based on commands CMD transferred from the memory controller. The command control logic 410 may include a command decoder 411 that decodes the commands CMD received from the memory controller 50 and one or more mode registers 412 that store control values for controlling operation of the semiconductor memory device 400.

Although FIG. 8 illustrates the command control logic 410 and the address register 420 as being distinct from each other, the command control logic 410 and the address register 420 may be implemented as a single integrated circuit. Alternatively or additionally, although FIG. 8 illustrates the command CMD and the address ADDR being provided as distinct signals, the command CMD and the address ADDR may be provided as a combined signals, e.g., as specified by DDR5, HBM and LPDDR5 standards.

FIG. 9 is a vertical cross-sectional diagram illustrating a semiconductor memory device according to some example embodiments, and FIG. 10 is a perspective diagram illustrating an example embodiment of a cell layer in the semiconductor memory device of FIG. 9. FIG. 9 illustrates local bitlines LBL and memory cells MC connected to a single global bitline GBL, and the structure illustrated in FIG. 9 may be repeatedly arranged in the second direction D2. Hereinafter, repeated descriptions with FIGS. 1 through 3 may be omitted.

Referring to FIGS. 9 and 10, in a semiconductor memory device 1003, each local bitline of the plurality of local bitlines LBL11 through LBL33 may be connected to one memory cell, e.g., only one memory cell, included in each cell layer. For example, each local bitline may be connected commonly to the same number of the memory cells MC as the number of cell layers T1 through T4.

As shown in FIG. 9, the semiconductor memory device 1003 may include the plurality of memory cells MC, and the plurality of memory cells MC may form the plurality of cell layers T1 through T4 that are spaced apart and stacked in the first direction D1. FIG. 10 illustrates the structure of one cell layer, for example, the first cell layer T1, and the second through fourth cell layers T2 through T4 may have the same structure as the first cell layer T1.

According to some example embodiments, the memory cells MC may be implemented as dynamic random access memory (DRAM) cells. Each memory cell MC may include or may be one cell transistor CT and one cell capacitor CC, e.g., each memory cell MC may be a 1T1C memory cell. The cell transistor CT is connected between the corresponding one local bitline LBL and a first capacitor electrode of the cell capacitor CC (e.g., first capacitor electrode 315 in FIGS. 16 through 46), and the cell transistor CT may be turned on (e.g., the corresponding memory cell is selected) based on the voltage of a corresponding wordline connected to the gate electrode of the cell transistor CT from among the plurality of wordlines WL11 through WL13. A first voltage VP may be applied to the second capacitor electrode of the cell capacitor CC (e.g., the second capacitor electrode 335 of FIGS. 16 through 46).

As shown in FIG. 10, the second capacitor electrodes 335 of the plurality of memory cells MC may be electrically connected to each other via vertical conductive paths VL and at least one horizontal conductive path HL. The vertical conductive paths VL and the at least one horizontal conductive path HL may form a common node such that the first voltage VP may be applied to at least one location of the vertical conductive paths VL and the at least one horizontal conductive path HL.

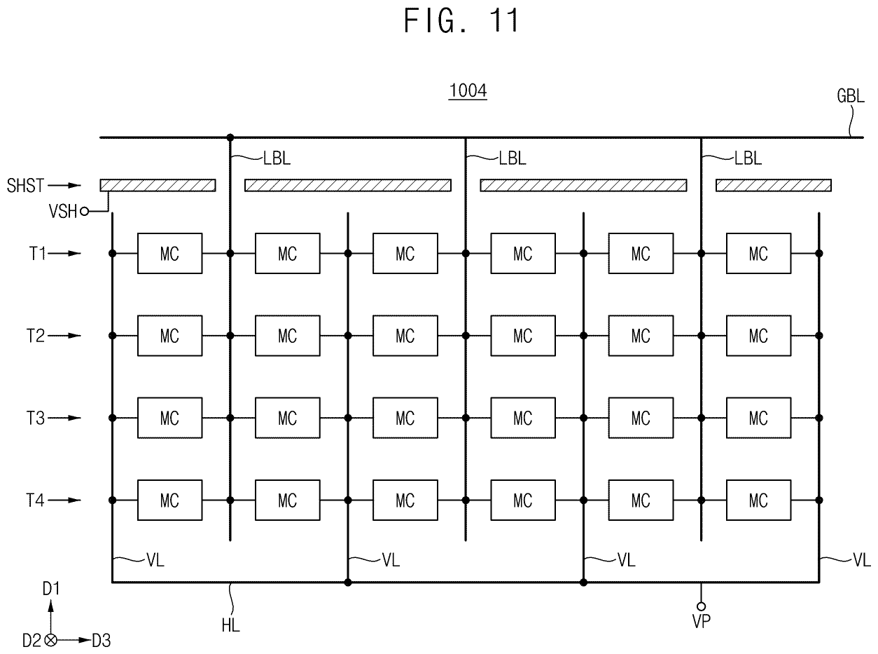

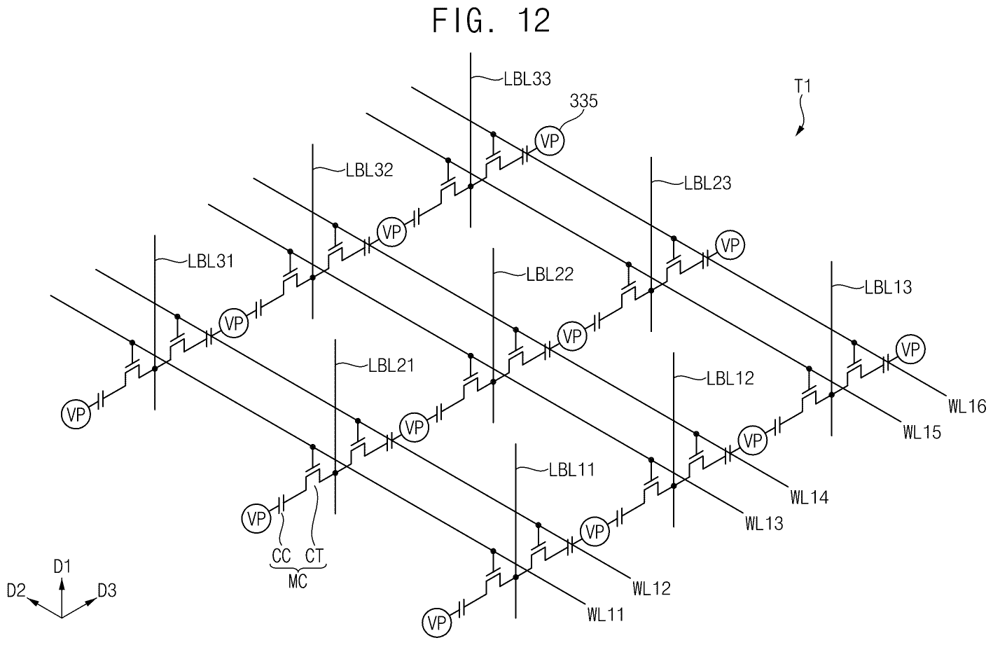

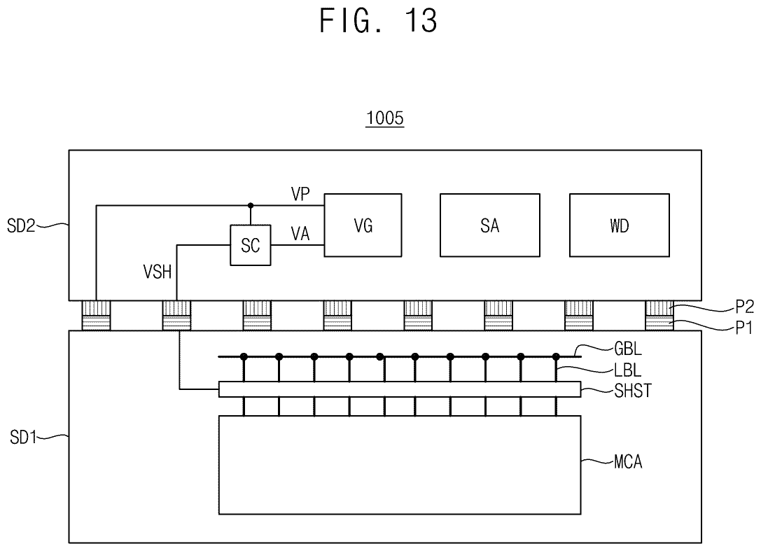

FIG. 11 is a vertical cross-sectional diagram illustrating a semiconductor memory device according to some example embodiments, and FIG. 12 is a perspective diagram illustrating some example embodiments of a cell layer in the semiconductor memory device of FIG. 11. FIG. 11 illustrates local bitlines LBL and memory cells MC connected to a single global bitline GBL, and the structure illustrated in FIG. 11 may be repeatedly arranged in the second direction D2. Hereinafter, repeated descriptions with FIGS. 1 through 3 may be omitted.

Referring to FIGS. 11 and 12, in a semiconductor memory device 1004, each local bitline of the plurality of bitlines LBL11 through LBL33 may be connected two memory cells, e.g., only two memory cells, included in each cell layer. For example, each local bitline may be connected commonly to the same number of the memory cells MC as twice the number of cell layers T1 through T4.

As shown in FIG. 11, the semiconductor memory device 1004 may include the plurality of memory cells MC, and the plurality of memory cells MC may form the plurality of cell layers T1 through T4 that are spaced apart and stacked in the first direction D1. FIG. 12 illustrates the structure of one cell layer, e.g., the first cell layer T1, and the second through fourth cell layers T2 through T4 may have the same structure as the first cell layer T1.

According to some example embodiments, the memory cells MC may be implemented as dynamic random access memory (DRAM) cells. Each memory cell MC may include one cell transistor CT and one cell capacitor CC, e.g., may be a 1T1C memory cell. The cell transistor CT is connected between a corresponding one local bitline LBL and a first capacitor electrode of the cell capacitor CC (e.g., first capacitor electrode 315 in FIGS. 16 through 46), and the cell transistor CT may be turned on (i.e., the corresponding memory cell is selected) based on the voltage of a corresponding wordline connected to the gate electrode of the cell transistor CT from among the plurality of wordlines WL11 through WL16. A first voltage VP may be applied to the second capacitor electrode of the cell capacitor CC (e.g., the second capacitor electrode 335 of FIGS. 16 through 46).

As shown in FIG. 12, the second capacitor electrodes 335 of the plurality of memory cells MC may be electrically connected to each other via vertical conductive paths VL and at least one horizontal conductive path HL. The vertical conductive paths VL and the at least one horizontal conductive path HL may form a common node such that a first voltage VP may be applied to at least one location of the vertical conductive paths VL and the at least one horizontal conductive path HL.

The semiconductor memory device 1003 of FIGS. 9 and 10 includes a relatively larger number of local bitlines than the semiconductor memory device 1004 of FIGS. 11 and 12, such that the number of memory cells connected to one local bitline is relatively small in the semiconductor memory device 1003 of FIGS. 9 and 10. Accordingly, the semiconductor memory device 1003 of FIGS. 9 and 10 may have better electrical characteristics than the semiconductor memory device 1004 of FIGS. 11 and 12. On the other hand, the length in the third direction D3 of the semiconductor memory device 1004 of FIGS. 11 and 12 may be implemented smaller than the length in the third direction D3 of the semiconductor memory device 1003 of FIGS. 9 and 10.

In some example embodiments, each or at least one memory cell MC may be implemented with a memristor in lieu of, or in addition to, a capacitor. For example, in some example embodiments each memory cell MC may be a 1T1M, or one transistor, one memristor memory cell. In some example embodiments, at least one memory cell MC may have hysteresis behavior. Example embodiments are not limited thereto.

FIG. 13 is a diagram illustrating a semiconductor memory device according to some example embodiments.

Referring to FIG. 13, a semiconductor memory device 1005 may include a first semiconductor die SD1 and a second semiconductor die SD2. The second semiconductor die SD2 may be stacked on the first semiconductor die SD1 in the first direction D1 perpendicular to the semiconductor substrate.

The first semiconductor die SD1 may include first pads PD1 and the second semiconductor die SD2 may include second pads PD2. By connecting the first pad PD1 and the second pad PD2 to each other, the circuits of the first semiconductor die SD1 and the circuits of the second semiconductor die SD2 may be electrically connected to each other. The semiconductor memory device 10005 may be a chip to chip (C2C) structure. A C2C structure may represent fabricating an upper chip on a first wafer, fabricating a lower chip on a second wafer that is different from the first wafer, and then connecting the upper chip (e.g., the second semiconductor die SD2) and the lower chip (e.g., the first semiconductor die SD1) to each other by a bonding method. For example, the bonding method may represent electrically connecting the bonding metal (e.g., the first pads P1) formed on the surface of the lower chip and the bonding metal (e.g., the second pads P2) formed on the surface of the upper chip. For example, if the bonding metal is formed of copper (Cu), the bonding method may be a Cu—Cu bonding method. According to some example embodiments, the bonding metal may also be formed of aluminum or tungsten.

The first semiconductor die SD1 may include a memory cell array MCA, a plurality of global bitlines GBL, a plurality of local bitlines LBL, and a shielding structure SHST.

As described above, the memory cell array MCA may include a plurality of memory cells disposed above a semiconductor substrate. The plurality of global bitlines GBL may be disposed above the memory cell array MCA in the first direction D1 perpendicular to the top surface of the semiconductor substrate, arranged in the second direction D2 parallel to the top surface of the semiconductor substrate, and extend in the third direction D3 parallel to the top surface of the semiconductor substrate. The plurality of local bitlines LBL may extend in the first direction D1 to connect the plurality of memory cells included in the memory cell array MCA and the plurality of global bitlines LBL. The shielding structure SHST may be disposed between the memory cell array MCA and the plurality of global bitlines GBL to shield electrical interference between the memory cell array MCA and the plurality of global bitlines GBL.

The second semiconductor die SD2 may include peripheral circuits for controlling the memory cell array MCA of the first semiconductor die SD1. For example, the second semiconductor die SD2 may include a wordline driver circuit WD, a sense amplifier circuit SA, a voltage generator VG, a switch circuit SC, and the like. Only components are shown in FIG. 8 to illustrate example embodiments, and the semiconductor memory device 1005 may further include various other components as described above with reference to FIG. 8.

The wordline driver circuit WD may select and enable one wordline based on an access address provided by the memory controller. The cell transistors included in the selected memory cells connected to the selected wordline may be turned on to perform a read operation, a write operation, or a refresh operation.

The sense amplifier circuit SA may sense data stored in the selected memory cells of the plurality of memory cells based on voltages on the plurality of global bitlines GBL.

The voltage generator VG may receive an external voltage to generate various voltages for operation of the semiconductor memory device 1005. The voltage generator VG may include one or more voltage regulators to generate respective voltages.

With respect to some example embodiments, the voltage generator VG may generate a first voltage VP and a second voltage VA. The first voltage VP may be a voltage applied commonly to a plurality of memory cells. For example, as described above with reference to FIGS. 10 and 12, the first voltage V1 may be a voltage applied commonly to the first capacitor electrodes 335 of the memory cells. The second voltage VA may be generated independently of the first voltage VP.

The switch circuit SC may provide a shielding voltage VSH that is applied to the shielding structure SHST based on the first voltage VP and the second voltage VA.

As the number of memory cells included in the semiconductor memory device increases, the fluctuation of the charges stored in the cell capacitors increases during sensing operation, which increases the voltage fluctuation of the first voltage VP. These voltage fluctuations may affect the voltages developed on the global bitlines during the sensing operation and increase sensing errors.

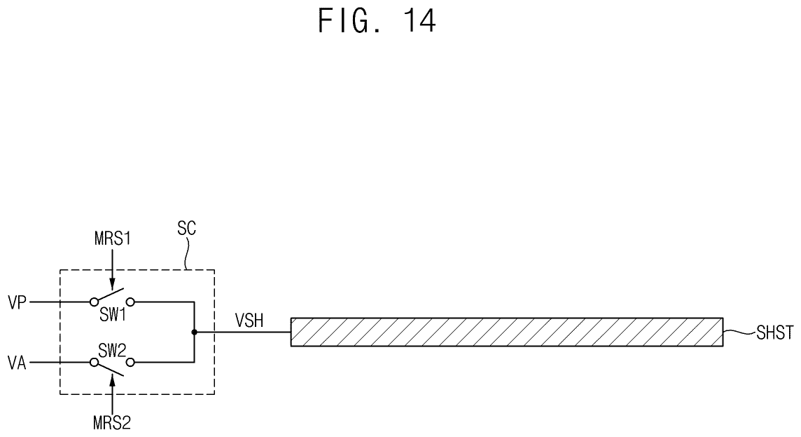

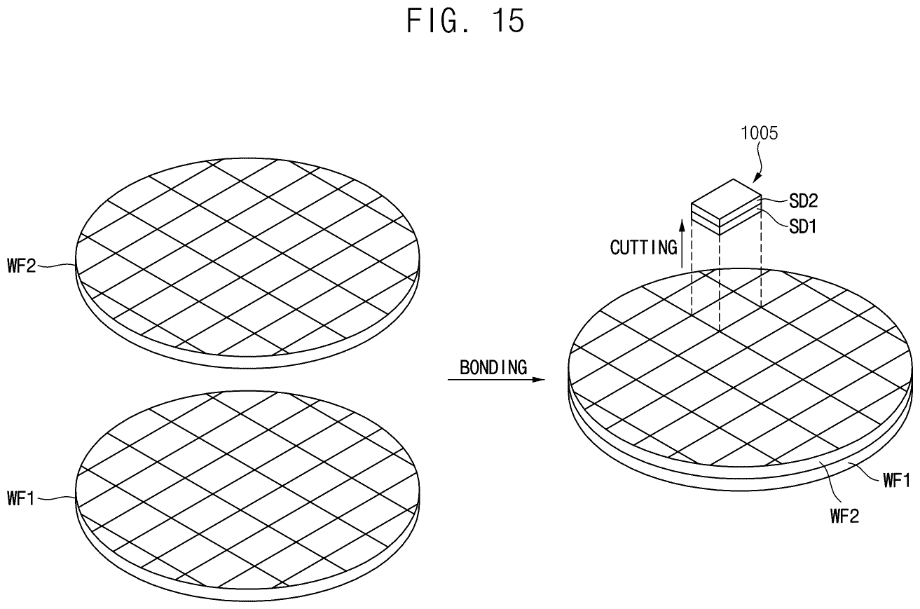

FIG. 14 is a diagram illustrating some example embodiments of a switch circuit in the semiconductor memory device of FIG. 13.

Referring to FIG. 14, a switch circuit SC may include a first switch SW1 and a second switch SW2.

The first switch SW1 may apply a first voltage VP, which is applied commonly to the plurality of memory cells, to the shielding structure SHST in response to a first switch signal MRS1. The second switch SW2 may apply a second voltage VA independent of the first voltage VP to the shielding structure SHST in response to the second switch signal MRS2. In some example embodiments, either or both of the first switch SW1 and the second switch SW2 may be implemented as transistors such as but not limited to NMOS transistors; example embodiments are not limited thereto.

If the first voltage VP is highly variable due to insufficient capacitance of the node to which the first voltage VP is applied (e.g., the second capacitor electrode 335 in FIGS. 16 through 46), the first switch signal MRS1 may be activated and the second switch signal MRS2 may be deactivated to apply the first voltage VP to the shielding structure SHST as a shielding voltage VSH. By applying the first voltage VP to the second capacitor electrode 335 and the shielding structure SHST in common, the effective capacitance of the second capacitor electrode 335 may be increased and the voltage fluctuation of the second capacitor electrode 335 may be reduced.

On the other hand, if the coupling between the global bitlines and the second capacitor electrode 335 to which the first voltage VP is applied is larger, the second voltage VA generated independently of the first voltage VP may be applied to the shielding structure SHST as the shielding voltage VSH by activating the second switch signal MRS2 and deactivating the first switch signal MRS1. By applying the independent voltages VP and VA to the second capacitor electrode 335 and the shielding structure SHST, respectively, electrical interference between the global bitlines and the second capacitor electrode 335 may be blocked or reduced.

As described above with reference to FIG. 8, the semiconductor memory device may include the one or more mode registers 412 that store control values for controlling operation of the semiconductor memory device. The semiconductor memory device (e.g., the command control logic 410 of FIG. 8) may selectively activate one of the first switch signal MRS1 and the second switch signal MRS2 based on the value stored in the mode registers 412.

During testing or probing of the semiconductor memory device, the performance and/or the yield of the semiconductor memory device may be evaluated by applying the first voltage VP and the second voltage VA to the shielding structure SHST, respectively. Based on the results of these tests, the control value for determining the shielding voltage VSH may be set as one of the mode register options of the DRAM device.

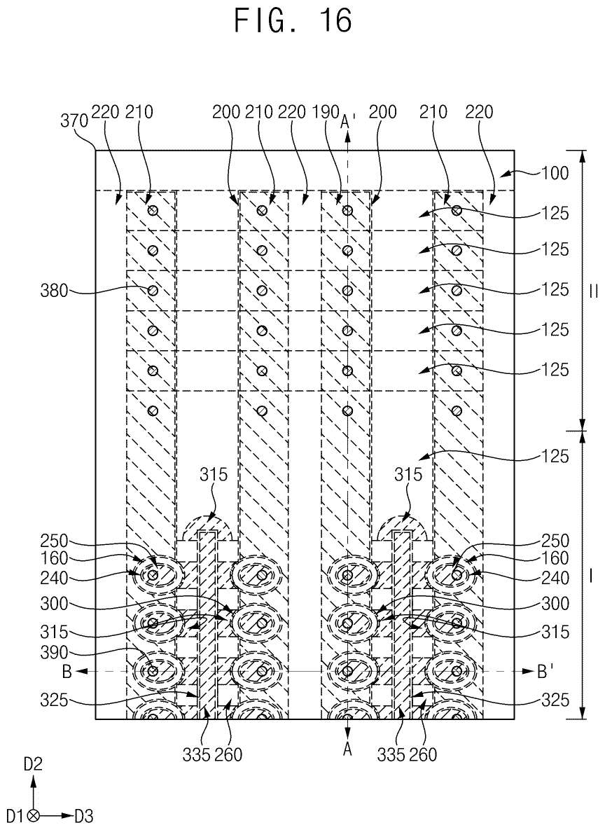

FIG. 15 is a diagram illustrating a manufacturing process of the semiconductor memory device of FIG. 13.

Referring to FIG. 15, respective integrated circuits are formed on a first wafer WF1 and a second wafer WF2. The first semiconductor die SD1 described above with reference to FIG. 13 may be formed on the first wafer WF1, and the second semiconductor die SD2 described above with reference to FIG. 13 may be formed on the second wafer WF2. The cut portion of the first wafer WF1 corresponds to a respective first semiconductor die SD1, and a cut portion of the second wafer WF2 corresponds to a respective second semiconductor die SD2. In some example embodiments, a diameter of the first wafer WF1 and a diameter of the second wafer WF2 may be 200 mm, 300 mm, or 450 mm; example embodiments are not limited thereto. In some example embodiments, each of the first semiconductor die SD1 and the second semiconductor die SD2 may be rectangular, e.g., square; example embodiments are not limited thereto.

With the integrated circuits of the first wafer WF1 and the second wafer WF2 formed, the first wafer WF1 and the second wafer WF2 may be bonded by a bonding method. The bonded wafers WF1 and WF2 are cut or diced into a plurality of chips, each of which corresponds to the semiconductor memory device 1005 of FIG. 13 and includes stacked semiconductor dies SC1 and SC2.

Hereinafter, with reference to FIGS. 16 through 46, a semiconductor memory device and a method of manufacturing the semiconductor memory device according to some example embodiments will be described in detail. Referring to FIGS. 16 through 46, embodiments in which two memory cells included in a respective cell layer are connected to each of the local bit lines of FIGS. 11 and 12 are described, but example embodiments are not limited thereto. The descriptions of the local bit lines and the shielding structure described above are omitted in FIGS. 16 through 46.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Accordingly, “first”, “second” and/or “third” may be used selectively or interchangeably for each material, layer, region, electrode, pad, pattern, structure or process respectively.

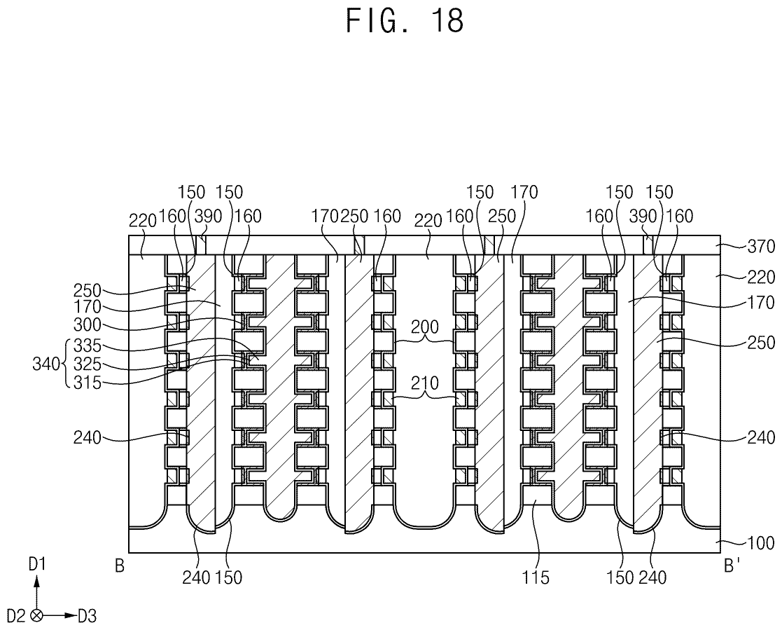

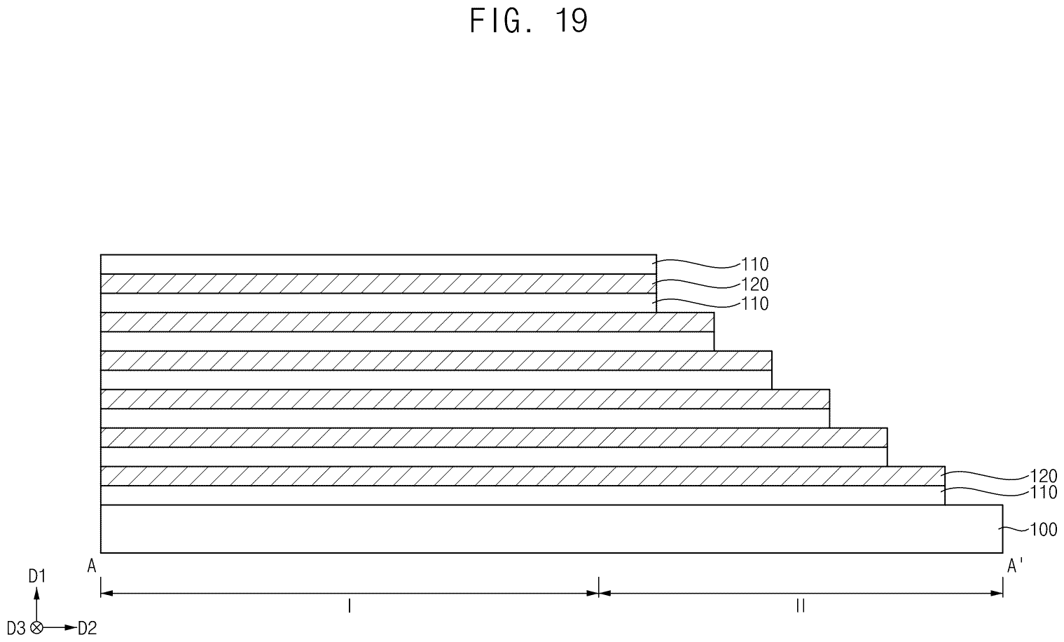

FIGS. 16, 17 and 18 are a plan view and cross-sectional views illustrating a semiconductor memory device according to some example embodiments. FIG. 16 is the plan view, FIG. 17 is a cross-sectional view taken along line A-A′ of FIG. 16, and FIG. 18 is a cross-sectional view taken along line B-B′ of FIG. 16.

In FIGS. 16 through 18, a semiconductor memory device may include a first gate electrode 210, a first gate insulation layer 200, a bitline 250, a channel 160, first and second ohmic contact patterns 240 and 300, a capacitor structure 340, and first and second contact plugs 380 and 390 on a substrate 100. The bitline corresponds to the local bitline as described above.

The semiconductor memory device may further include first, third, fourth, and fifth insulation patterns 115, 170, 220, and 260, a second insulation layer 150, first insulating interlayer 130, and a second insulating interlayer 370.

The substrate 100 may include a semiconductor material, e.g., one or more of silicon, germanium, silicon-germanium, etc., or a III-V group compound semiconductor, such as GaP, GaAs, GaSb, etc. In some example embodiments, the substrate 100 may be a silicon-on-insulator (SOI) substrate or a germanium-on-insulator (GOI) substrate. In some example embodiments, the substrate 100 may be doped, e.g., may be lightly doped with impurities such as boron; example embodiments are not limited thereto.

The substrate 100 may include a first region I and a second region II. The first region I may be a cell region on which memory cells are formed, and the second region II may be an extension region or a pad region on which contact plugs for transferring electrical signals to the memory cells are formed. In some example embodiments, the second region II may surround the first region I. Alternatively, the second region II may be disposed at opposite sides of the first region I in the second direction D2.

The first gate electrode 210 may extend in the second direction D2 on the first region I and the second region II of the substrate 100, and a plurality of first gate electrodes 210 may be spaced apart from each other in the first direction D1 to form a first gate electrode structure. The first insulation pattern 115 may be disposed between neighboring ones of the first gate electrodes 210 in the first direction D1, and the first insulation pattern 115 may also be disposed between the substrate 100 and a lowermost one of the first gate electrodes 210 and on an uppermost one of the first gate electrodes 210. Each of the first gate electrodes 210 may serve as a wordline of the semiconductor memory device, and the first gate electrode structure may also be referred to as a wordline structure.

In some example embodiments, extension lengths in the second direction D2 of the first gate electrodes 210 may decrease from a lowermost level to an uppermost level in a stepwise manner, and the first gate electrode structure may have a staircase shape. A portion of each of the first gate electrodes 210 not overlapped by ones of the first gate electrodes 210 over each of the first gate electrodes 210, that is, an end portion in the second direction D2 of each of the first gate electrodes 210 may be referred as a pad. In some example embodiments, the pads may be disposed in the second direction D2 on the second region II of the substrate 100. The first gate electrode 210 may include, e.g., one or more of a metal, a metal nitride, a metal silicide, doped polysilicon, etc.

In some example embodiments, a plurality of first gate electrode structures may be spaced apart from each other in the third direction D3, and the fourth insulation pattern 220 and the first sacrificial pattern 125 may be alternately and repeatedly disposed in the third direction D3 between the first gate structures. The fourth insulation pattern 220 may extend in the second direction D2 on the first region I and the second region II of the substrate 100 through the first gate electrode structure and the first insulation patterns 115. The first sacrificial pattern 125 and the first insulation pattern 115 may be alternately and repeatedly stacked in the first direction D1, and may extend through the first gate electrode structure between ones of the fourth insulation patterns 220 neighboring in the third direction D3 to divide the first gate electrode structure into two parts in the third direction D3.

Each of the first insulation pattern 115 and the fourth insulation pattern 220 may include an oxide, e.g., silicon oxide, and the first sacrificial pattern 125 may include a material having an etching selectivity with respect to the first insulation pattern 115, e.g., an insulating nitride such as silicon nitride. Each of the first insulation pattern 115 and the fourth insulation pattern 220 may include the same, or different, materials; example embodiments are not limited thereto.

The first gate insulation layer 200 may cover upper and lower surfaces of the first gate electrode 210, a sidewall facing the first sacrificial pattern 125, and a sidewall facing the channel 160 of the first gate electrode 210, and may also be formed on a sidewall of the first insulation pattern 115 facing the fourth insulation pattern 220. The first gate insulation layer 200 may include an oxide, e.g., silicon oxide.

The bitline 250 may be disposed on the first region I of the substrate 100, and may have a shape of a pillar extending in the first direction D1. The bitline 250 may extend through the first gate electrode structure and the first insulation patterns 115. In some example embodiments, a plurality of bitlines 250 may extend through the first gate electrode structure extending in the second direction D2, and may be spaced apart from each other in the second direction D2. Accordingly, a plurality of bitlines 250 may be spaced apart from each other in the second direction D2 and the third direction D3. The bitline 250 may include, e.g., a metal, a metal nitride, a metal silicide, doped polysilicon, etc.

The third insulation pattern 170 may be disposed on the first region I of the substrate 100, and may have a pillar shape extending through the first gate electrode structure and the first insulation patterns 115. In some example embodiments, the third insulation pattern 170 may contact a sidewall of the bitline 250 in the third direction D3, and the third insulation pattern 170 together with the bitline 250 may have a shape of, e.g., a circle, an ellipse, a polygon, a polygon with rounded corners, etc., in a plan view. Each of the bitline 250 and the third insulation pattern 170 may extend through an upper portion of the substrate 100, and in some example embodiments, a lowermost surface of the bitline 250 may be lower than a lowermost surface of the third insulation pattern 170. The third insulation pattern 170 may include an oxide, e.g., silicon oxide.

The channel 160 may be disposed at a level where each of the first gate electrodes 210 is disposed, and may surround sidewalls of the bitline 250 and the third insulation pattern 170. The channel 160 may contact the sidewall of the third insulation pattern 170, and the first ohmic contact pattern 240 may be disposed between the channel 160 and the bitline 250. The first gate insulation layer 200 may be disposed between the channel 160 and the first gate electrode 210.

Lower and upper surfaces of the channel 160 may be covered by the second insulation layer 150, and the second insulation layer 150 may contact a sidewall of a portion of the first insulation pattern 115 between neighboring ones of the channels 160 in the first direction D1 and a sidewall of a portion of the third insulation pattern 170 opposite thereto. Additionally, the second insulation layer 150 may cover a lower surface of the third insulation pattern 170, and may also contact the upper surface of the substrate 100. The second insulation layer 150 may include an oxide, e.g., silicon oxide, and in some cases, may be merged with the first insulation pattern 115 and/or the third insulation pattern 170.

In some example embodiments, the channel 160 may have a shape of a circular ring, an elliptical ring, a polygonal ring, etc. The channel 160 may be disposed at each level where the first gate electrode 210 is disposed, and a plurality of channels 160 may be disposed in the first direction D1. The channel 160 may surround the sidewalls of the bitline 250 and the third insulation pattern 170, and a plurality of channels 160 may be spaced apart from each other in the second and third directions D2 and D3.

The channel 160 may include a semiconductor material, e.g., one or more of silicon, germanium, silicon-germanium, etc., or an oxide semiconductor material. The oxide semiconductor material may include at least one of zinc tin oxide (ZTO), indium zinc oxide (IZO), zinc oxide (ZnOx), indium gallium zinc oxide (IGZO), indium gallium silicon oxide (IGSO), Indium oxide (InOx, In2O3), tin oxide (SnO2), titanium oxide (TiOx), zinc oxide nitride (ZnxOyNz), magnesium zincoxide (MgxZnyOz), indium zinc oxide (InxZnyOa), indium gallium zinc oxide (InxGayZnzOa), zirconium indium zinc oxide (ZrxInyZnzOa), hafnium indium zinc oxide (HfxInyZnzOa), tin indium zinc oxide (SnxInyZnzOa), aluminum tin indium zinc oxide (AlxSnyInzZnaOd), silicon indiumzinc oxide (SixInyZnzOa), zinc tin oxide (ZnxSnyOz), aluminum zinc tin oxide (AlxZnySnzOa), gallium zinc tin oxide (GaxZnySnzOa), zirconium zinc tin oxide (ZrxZnySnzOa) and indium gallium silicon oxide (InGaSiO).

The first ohmic contact pattern 240 may cover a lower surface of the bitline 250, and may also contact the upper surface of the substrate 100. The first ohmic contact pattern 240 may include a metal silicide, e.g., cobalt silicide, nickel silicide, titanium silicide, etc.

In some example embodiments, the first ohmic contact pattern 240 may not be formed between the channel 160 and the sidewall of the bitline 250, and in this case, for example, n-type impurity region or a p-type impurity region may be formed at a lateral portion of the channel 160 facing the sidewall of the bitline 250 so as to serve as the first ohmic contact pattern 240.

The capacitor structure 340 may include a first capacitor electrode 315, a dielectric pattern 325, and a second capacitor electrode 335 sequentially stacked. The second capacitor electrode 335 may include an extension portion extending through the first insulation patterns 115 in the first direction D1 and the second direction D2 and a first protrusion portion protruding in the third direction D3 from each of opposite sidewalls in the third direction D3 of the extension portion on the first region I of the substrate 100. In some example embodiments, the second capacitor electrode 335 may include a plurality of first protrusion portions facing sidewalls in the third direction D3 of corresponding ones, respectively, of the channels 160. Accordingly, the second capacitor electrode 335 may include a plurality of first protrusion portions spaced apart from each other in the first direction D1 and the second direction D2 on each of opposite sidewalls in the third direction D3.

The second capacitor electrode 335 may further include a second protrusion portion protruding from each of end portions in the second direction D2 of the extension portion and having a shape of a semi-circle in a plan view. A plurality of second protrusion portions may be spaced apart from each other in the first direction D1, and the second protrusion portions may be disposed at respective levels where the channels are disposed.

The dielectric pattern 325 may cover a sidewall and a lower surface of the second capacitor electrode 335. The dielectric pattern 325 may cover lower and upper surfaces, opposite sidewalls in the second direction D2, and a sidewall in the third direction D3 of each of the first protrusion portions of the second capacitor electrode 335.

The first capacitor electrode 315 may cover lower and upper surfaces and a sidewall of a portion of the dielectric pattern 325 covering the lower and upper surfaces and the sidewalls of the first protrusion portion of the second capacitor electrode 335. A plurality of first capacitor electrodes 315 may be spaced apart from each other in the second direction D2 and the third direction D3 correspondingly to the channels 160, and may also be spaced apart from each other in the first direction D1. Each of the first capacitor electrodes 315 may be disposed at a level where a corresponding one of the channels 160 is disposed.

In the capacitor structure 340, each of the first capacitor electrodes 315, a portion of the dielectric pattern 325 that is disposed at the same level as each of the first capacitor electrodes 315, and a portion of the second capacitor electrode 335 at the same level as the portion of the dielectric pattern 325 may collectively form a capacitor. Accordingly, the capacitor structure 340 may include a plurality of capacitors spaced apart from each other in the second direction D2 and the third direction D3 correspondingly to the layout of the first capacitor electrodes 315, and a plurality of capacitors may also be disposed at a plurality of levels, respectively, in the first direction D1.

In some example embodiments, an outer sidewall in the third direction D3 of the first capacitor electrode 315 of each of the capacitors may contact the second ohmic contact pattern 300, and may be electrically connected to the channel 160 through the second ohmic contact pattern 300. The outer sidewall in the third direction D3 of the first capacitor electrode 315 of each of the capacitors may face the sidewall of the bitline 250 at least partially covered by the channel 160. Additionally, an outer sidewall in the second direction D2 of the first capacitor electrode 315 may contact the fifth insulation pattern 260.

The first capacitor electrode 315 may alternatively or additionally be formed on lower and upper surfaces and a sidewall of a portion of the dielectric pattern 325 covering lower and upper surfaces and a sidewall of the second protrusion portion of the second capacitor electrode 335.

The fifth insulation pattern 260 may extend in the first direction D1 through the first insulation patterns 115 on the first region I of the substrate 100, and may be disposed between neighboring ones of the first capacitor electrodes 315 in the second direction D2 at each of opposite sides of the second capacitor 335 in the third direction D3. For example, the neighboring ones of the first capacitor electrodes 315 in the second direction D2 may be spaced apart from each other by the fifth insulation pattern 260 to be electrically insulated from each other. Accordingly, a plurality of fifth insulation patterns 260 may be spaced apart from each other in the second direction D2 at each of opposite sides of the second capacitor electrode 335 in the third direction D3.

The fifth insulation pattern 260 may also contact a sidewall of the first gate insulation layer 200. The fifth insulation pattern 260 may include an oxide, e.g., silicon oxide, or an insulating nitride, e.g., silicon nitride.

Each of the first capacitor 315 and the second capacitor 335 may independently or concurrently include, e.g., one or more of a metal, a metal nitride, a metal silicide, doped polysilicon, etc., and the dielectric pattern 320 may include a metal oxide having a high dielectric constant, e.g., hafnium oxide, zirconium oxide, etc.

The first insulating interlayer 130 and the second insulating interlayer 370 may be sequentially stacked in the first direction D1 on the substrate 100, the first insulating interlayer 130 may cover sidewalls of the first gate electrode structure and the first insulation patterns 115, and the second insulating interlayer 370 may be disposed on the first insulating interlayer 130, the first gate electrode structure, the bitline 250, the capacitor structure 340, the third to fifth insulation patterns 170, 220, and 260, and the second insulation layer 150. Each of the first insulating interlayer 130 and the second insulating interlayer 370 may include an oxide, e.g., silicon oxide.

The first contact plug 380 may extend through the first insulating interlayer 130 and the second insulating interlayer 370 and the first gate insulation layer 200 to contact an upper surface of a pad of each of the first gate electrodes 200 on the first region I of the substrate 100, and the second contact plug 390 may extend through the second insulating interlayer 370 to contact an upper surface of the bitline 250 on the first region I of the substrate 100.

A third contact plug extending through the second insulating interlayer 370 to contact an upper surface of the second capacitor electrode 335 may be further formed. Each of the first contact plug 380, the second contact plug 390, and the third contact plug may include a metal, a metal nitride, a metal silicide, doped polysilicon, etc.

As illustrated above, in the semiconductor memory device, the channel 160 and the first capacitor electrode 315 may be disposed at the same level as each of the first gate electrodes 210, and, when compared to a case in which the first gate electrode 210 is disposed over and/or under the channel 160 and the first capacitor electrode 315, a thickness in the first direction D1, that is, in the vertical direction of a memory cell including the first gate electrode 210, the channel 160 and the capacitor electrode 315 may be reduced. Accordingly, a vertical thickness and/or a height of the upper surface of the semiconductor memory device may be reduced.

The channel 160 may surround the sidewalls of the bitline 250 and the third insulation pattern 170, and the first capacitor electrodes 315, the channels 160, and the bitlines 250 at opposite sides, respectively, in the third direction D3 may be symmetrical with reference to the extension portion of the second capacitor 335 extending in the second direction D2. Additionally or alternatively, the bitline 250, the first capacitor electrode 315, and a portion of the channel 160 therebetween may be disposed in the third direction D3 that is perpendicular to the extension direction of the first gate electrode 210.

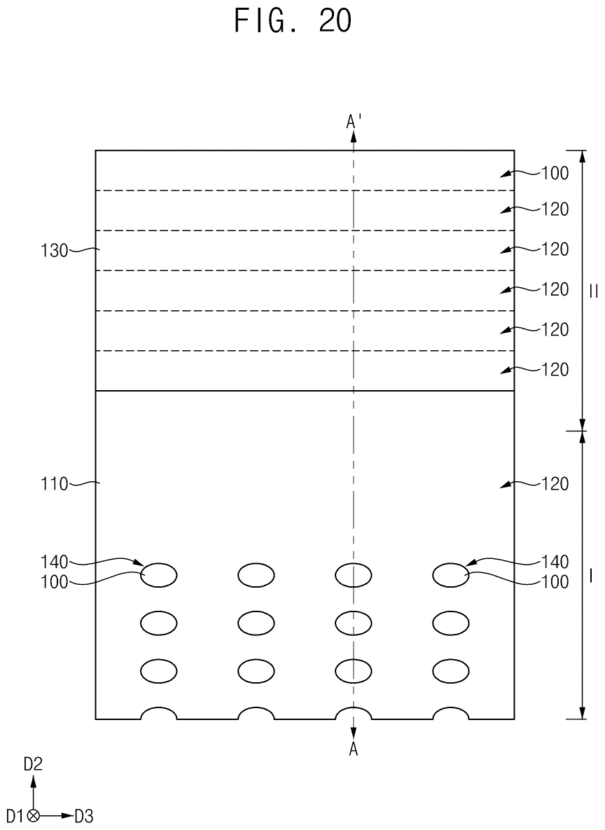

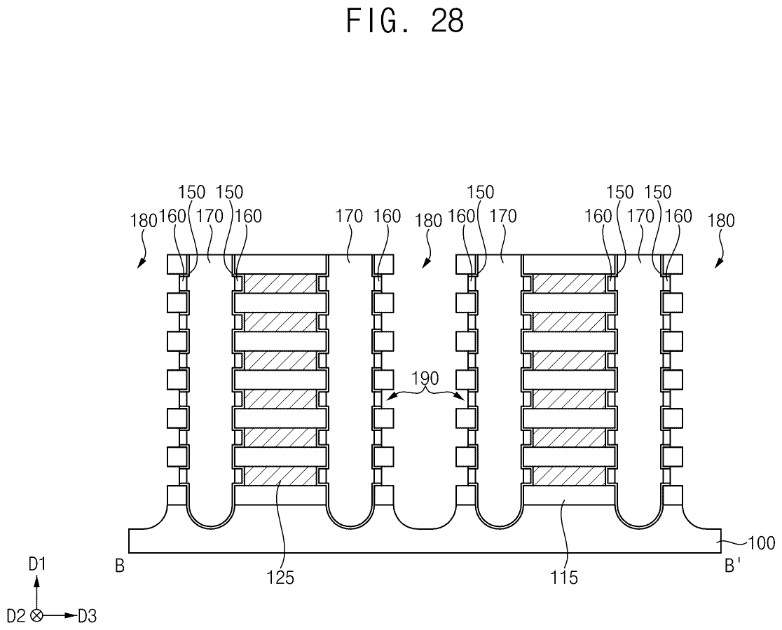

FIGS. 19 through 46 are plan views and cross-sectional views illustrating example embodiments of manufacturing a semiconductor memory device according to some example embodiments. FIGS. 20, 24, 26, 29, 34, 37, 40-41, 43 and 45 are the plan views, FIGS. 19, 21-23, 25, 27, 30, 32, 35 and 38 are cross-sectional views taken along lines A-A′ of corresponding plan views, respectively, and FIGS. 28, 31, 33, 36, 39, 42, 44 and 46 are cross-sectional views taken along lines B-B′ of corresponding plan views, respectively.

In FIG. 19, a first insulation layer 110 and a first sacrificial layer 120 may be alternately and repeatedly formed with a process such as but not limited to an atomic layer deposition (ALD) process to be stacked on a substrate 100 including a first region I and a second region II to form a mold layer, a photoresist pattern may be formed on the mold layer, and an etching process such as a dry etching process and/or a wet etching process using the photoresist pattern as an etching mask and a trimming process on the photoresist pattern may be alternately and repeatedly performed to form a mold having a staircase shape.

The first insulation layer 110 may include an oxide, e.g., silicon oxide, and the first sacrificial layer 120 may include a material having an etching selectivity with respect to the first insulation layer 110, e.g., an insulating nitride such as silicon nitride.

The mold may include step layers each of which may include the first insulation layer 110 and the first sacrificial layer 120 stacked in the first direction D1, and lengths in the second direction D2 of the step layers may decrease from a lowermost level to an uppermost level in a stepwise manner. Hereinafter, a portion of each of the step layers that is not overlapped by upper step layers in the first direction D1, that is, an end portion in the second direction D2 of each of the step layers may be referred to as a step.

In some example embodiments, the steps of the mold may be formed on the second region II of the substrate 100. FIG. 19 shows that each step layer includes the first insulation layer 110 and the first sacrificial layer 120 sequentially stacked in the first direction D1 in this order, however, example embodiments are not limited thereto, and for example, each step layer may include the first sacrificial layer 120 and the first insulation layer 110 sequentially stacked in the first direction D1 in this order.

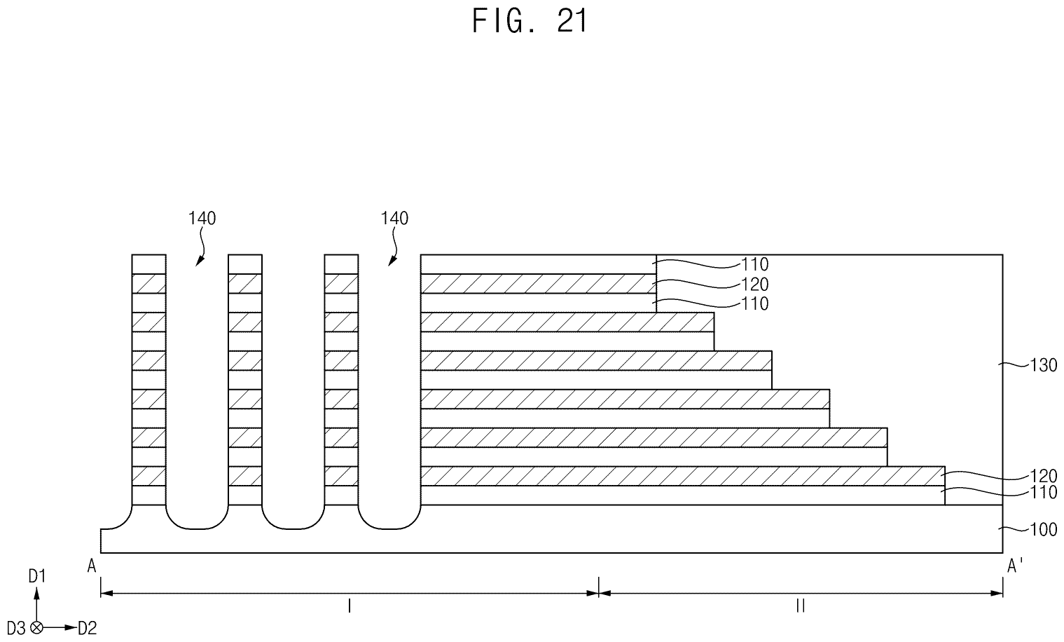

In FIGS. 20 and 21, a first insulating interlayer 130 may be formed on the substrate 100 to cover the mold, and a planarization process may be performed on the first insulating interlayer 130 until an upper surface of the mold is exposed, and the first insulating interlayer 130 may cover a sidewall of the mold. The planarization process may include, e.g., a chemical mechanical polishing (CMP) process and/or an etch back process.

An etching process such as an anisotropic etching process may be performed on a portion of the mold on the first region I of the substrate 100 to form a first hole 140 extending in the first direction D1 and exposing an upper surface of the substrate 100. The first hole 140 may also extend through an upper portion of the substrate 100, and a plurality of first holes 140 may be spaced apart from each other in the second direction D2 and the third direction D3. Each of the first holes 140 may have a shape of, e.g., a circle, an ellipse, a polygon, a polygon with rounded corners, etc.

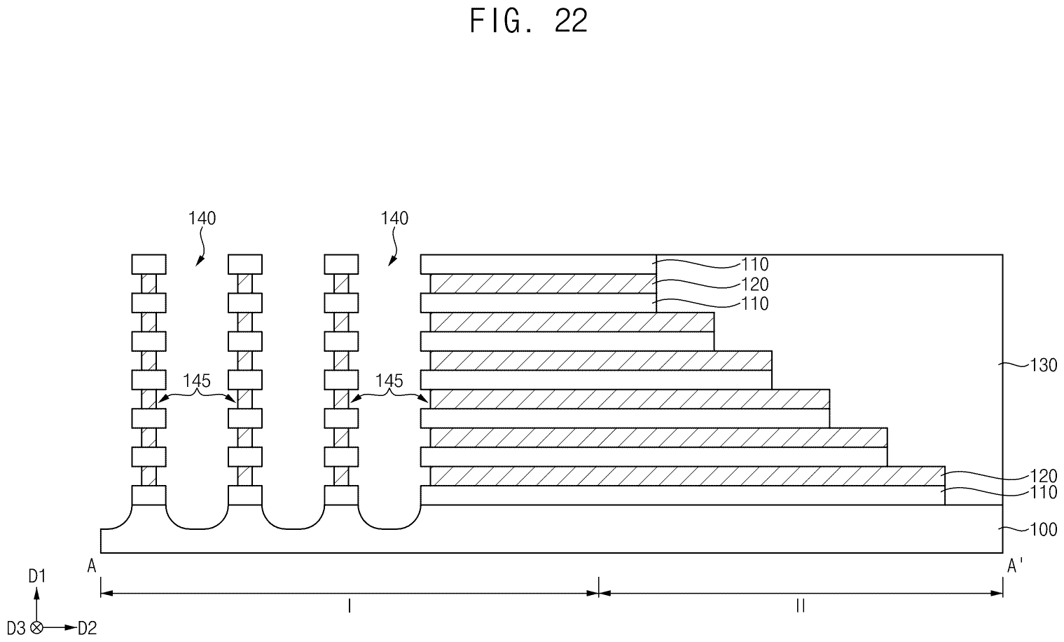

In FIG. 22, a lateral portion of the first sacrificial layer 120 exposed by the first hole 140 may be removed to form a first recess 145. In some example embodiments, the first recess 145 may be formed by performing, e.g., a wet etching process and/or another isotropic etching process on the first sacrificial layer 120, and a plurality of first recesses 145 connected to the first hole 140 may be formed to be spaced apart from each other in the first direction D1. Each of the first recesses 145 may have a shape of, e.g., a ring.

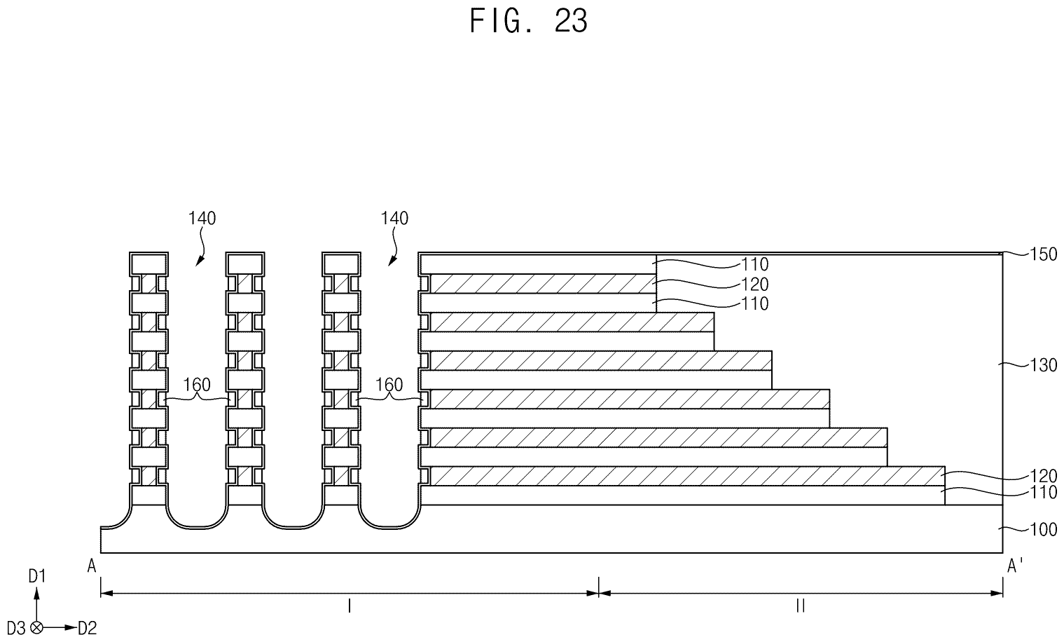

In FIG. 23, a second insulation layer 150 may be formed on inner walls of the first hole 140 and the first recess 145, an upper surface of the mold and an upper surface of the first insulating interlayer 130, a channel layer may be formed on the second insulation layer 150 to fill a portion of the first hole 140 and the first recess 145, and the channel layer may be partially removed to form a channel 160. The second insulation layer 150 may include an oxide, e.g., silicon oxide, and in some cases, may be merged with the first insulation layer 110.

The channel layer may be partially removed by, e.g., a wet etching process. In some example embodiments, a plurality of channels 160 may be spaced apart from each other in the first direction D1 along a sidewall of the first hole 140, and each of the channels 160 may have a shape of, e.g., a ring.

In some example embodiments, a plurality of channels 160 may be spaced apart from each other in the second direction D2 and the third direction D3 to form a channel array on the first region I of the substrate 100. The channel array may include a plurality of channel columns, each of which may include a plurality of channels 160 disposed in the second direction D2, spaced apart from each other in the third direction D3.

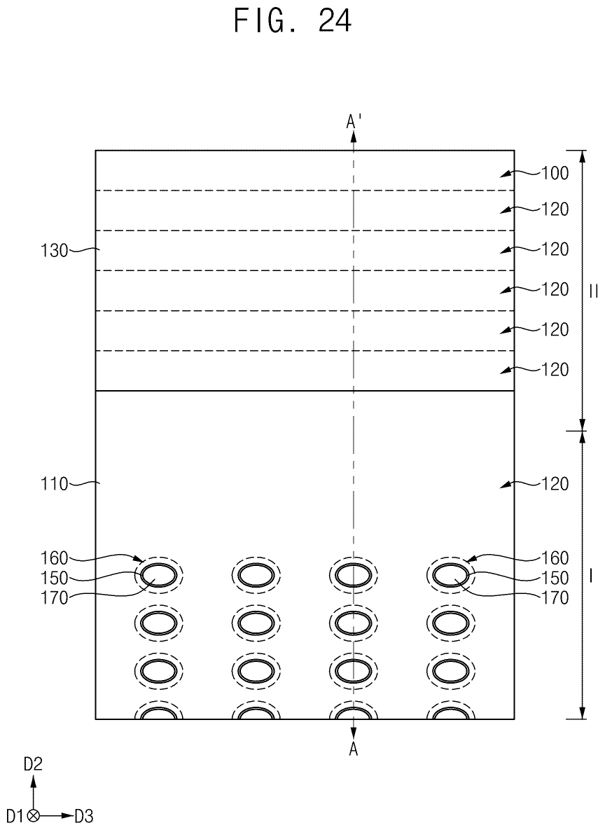

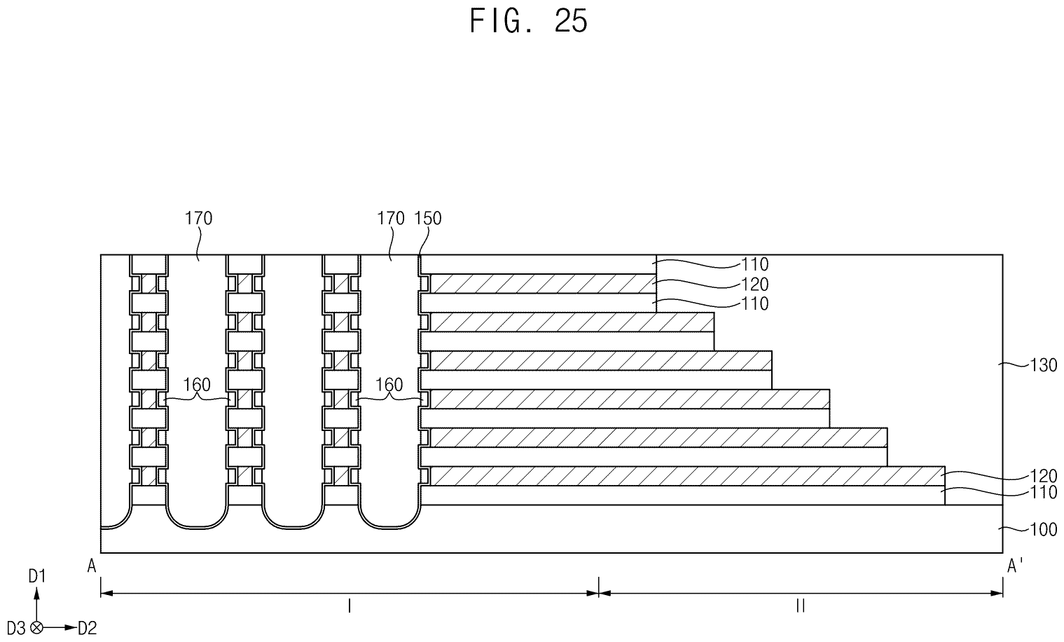

In FIGS. 24 and 25, a third insulation layer may be formed on the second insulation layer 150 and the channel 160 to fill the first hole 140, and a planarization process may be performed on the third insulation layer until the upper surface of the mold and an upper surface of the first insulating interlayer 130 are exposed to form a third insulation pattern 170 in the first hole 140. The third insulation pattern 170 may have a shape of a pillar extending in the first direction D1, and a plurality of third insulation patterns 170 may be spaced apart from each other in the second direction D2 and the third direction D3 on the first region I of the substrate 100.

During the planarization process, a portion of the second insulation layer 150 on the upper surface of the mold and the upper surface of the first insulating interlayer 140 may also be removed.

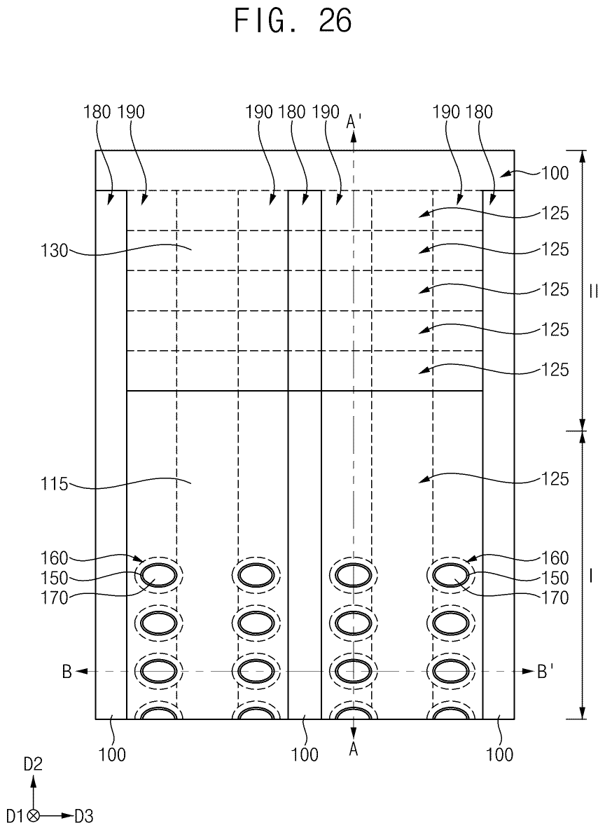

In FIGS. 26 to 28, a first opening 180 may be formed through the mold to expose the upper surface of the substrate 100, and the first opening 180 may also extend through the upper portion of the substrate 100.

In some example embodiments, the first opening 180 may extend to both opposite end portions of the mold in the second direction D2 on the first region I and the second region II of the substrate 100, and a plurality of first openings 180 may be spaced apart from each other in the third direction D3. As the first opening 180 is formed, the first insulation layer 110 may be divided into a plurality of first insulation patterns 115, each of which may extend in the second direction D2, spaced apart from each other in the third direction D3, and the first sacrificial layer 120 may be divided into a plurality of first sacrificial patterns 125, each of which may extend in the second direction D2, spaced apart from each other in the third direction D3.

In some example embodiments, each of the first openings 180 may be formed between neighboring ones of the channel columns in the third direction D3, and two channel columns may be disposed between neighboring ones of the first openings 180.

A lateral portion of the first sacrificial pattern 125 exposed by the first opening 180 and a portion of the second insulation layer 150 adjacent thereto may be removed to form a second recess 190 exposing a sidewall of the channel 160.

In some example embodiments, the second recess 190 may be formed by performing, e.g., a wet etching process and/or another isotropic etching process on the first sacrificial pattern 125 and the second insulation layer 150, and a plurality of second recesses 190 connected to the first opening 180 may be formed to be spaced apart from each other in the first direction D1. Each of the second recesses 190 may extend in the second direction D2 on the first region I and the second region II of the substrate 100. In some example embodiments, the second recess 190 may expose most of each of the channels 160 included in the channel column adjacent to the first opening 180.

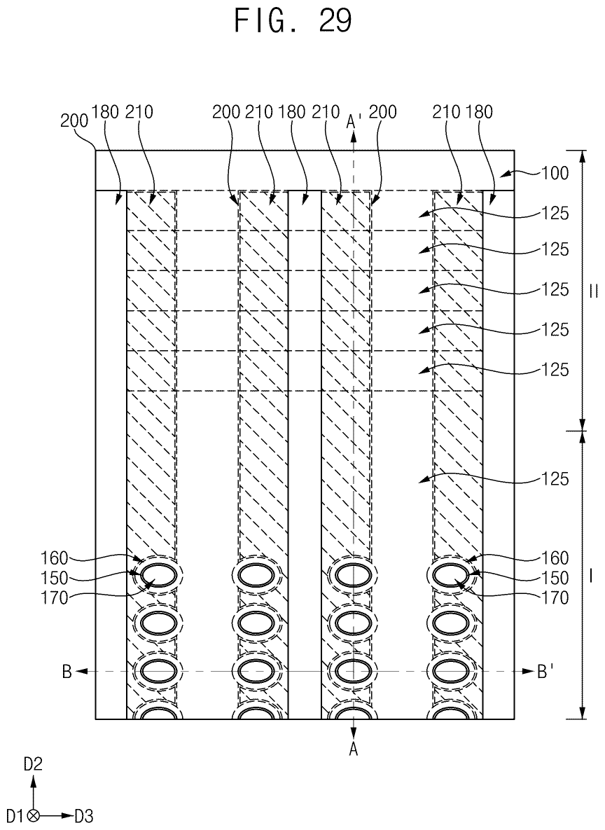

In FIGS. 29 to 31, a first gate insulation layer 200 may be formed on inner walls of the first opening 180 and the second recess 190, an upper surface of the third insulation pattern 170, an upper surface of the second insulation layer 150, the upper surface of the mold, and the upper surface of the first insulating interlayer 130, a first gate electrode layer may be formed on the first gate insulation layer 200 to fill a portion of the first opening 180 and the second recess 190, and the first gate electrode layer may be partially removed to form a first gate electrode 210. The first gate insulation layer 200 may include an oxide, e.g., silicon oxide, and in some cases, a portion of the second insulation layer 150 contacting the first gate insulation layer 200 may be merged thereto.

The first gate electrode layer may be partially removed by, e.g., a wet etching process. In some example embodiments, the first gate electrode 210 may extend in the second direction D2 at each of opposite sides in the third direction D3 of the first opening 180, and a plurality of first gate electrode layers may be formed to be spaced apart from each other in the third direction D3. Each of the first gate electrodes 210 may surround most of a sidewall of each of the channels 160 included in the channel column, and the first gate insulation layer 200 may be interposed between each of the first gate electrodes 210 and each of the channels 160.

A plurality of first gate electrodes 210 may be spaced apart from each other in the first direction D1 to form a first gate electrode structure. The first gate electrode structure may have a shape of a staircase having a length in the second direction D2 that may decrease from a lowermost level to an uppermost level in a stepwise manner. Hereinafter, each of opposite end portions of each of the first gate electrodes 210 in the first gate electrode structure that is not overlapped by upper ones of the first gate electrodes 210 in the first direction D1 may be referred to as a pad.

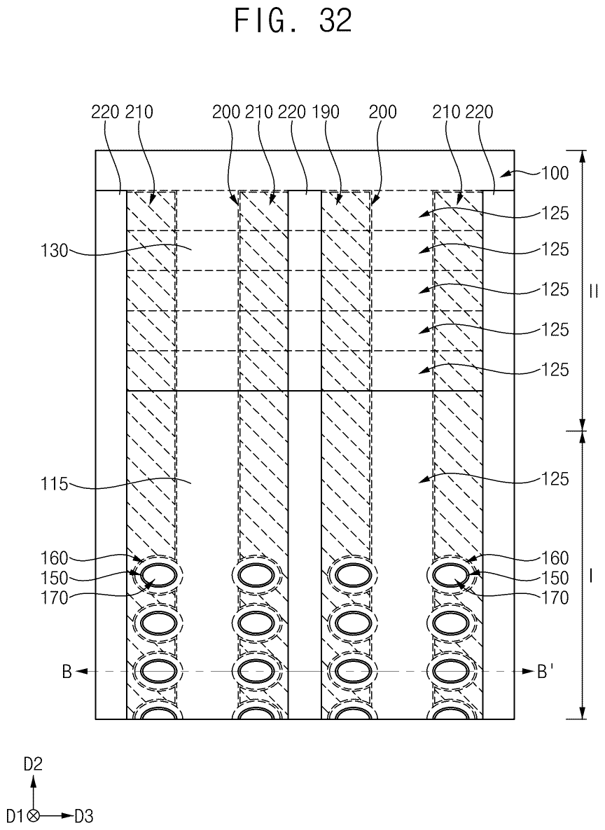

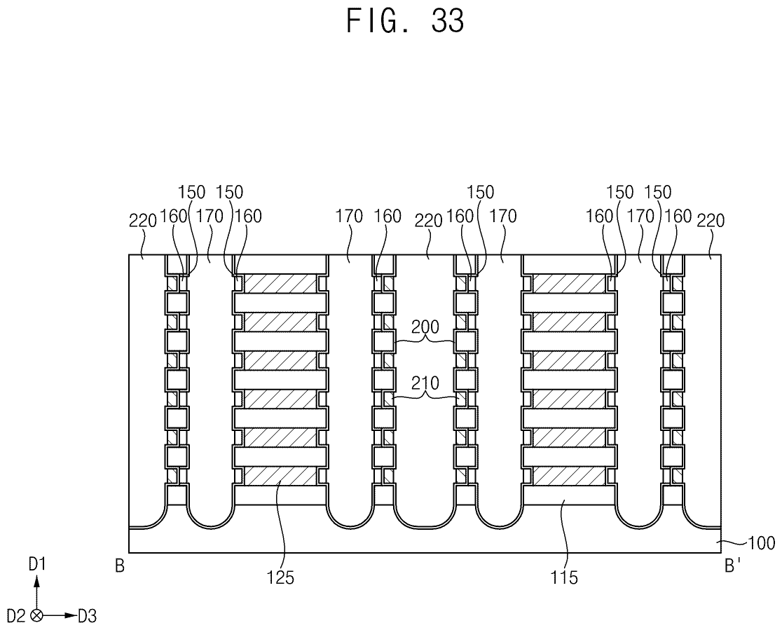

In FIGS. 32 and 33, a fourth insulation layer may be formed on the first gate insulation layer 200 and the first gate electrode 210 to fill the first opening 180, and a planarization process may be performed on the fourth insulation layer until the upper surfaces of the mold, the third insulation pattern 170, the second insulation layer 150, and the first insulating interlayer 130 are exposed to form a fourth insulation pattern 220 in the first opening 180.

The fourth insulation pattern 220 may extend in the second direction D2 on the first region I and the second region II of the substrate 100, and a plurality of fourth insulation patterns 220 may be spaced apart from each other in the third direction D3.

During the planarization process, a portion of the first gate insulation layer 200 on the upper surfaces of the mold, the third insulation pattern 170 and the first insulating interlayer 130 may also be removed.

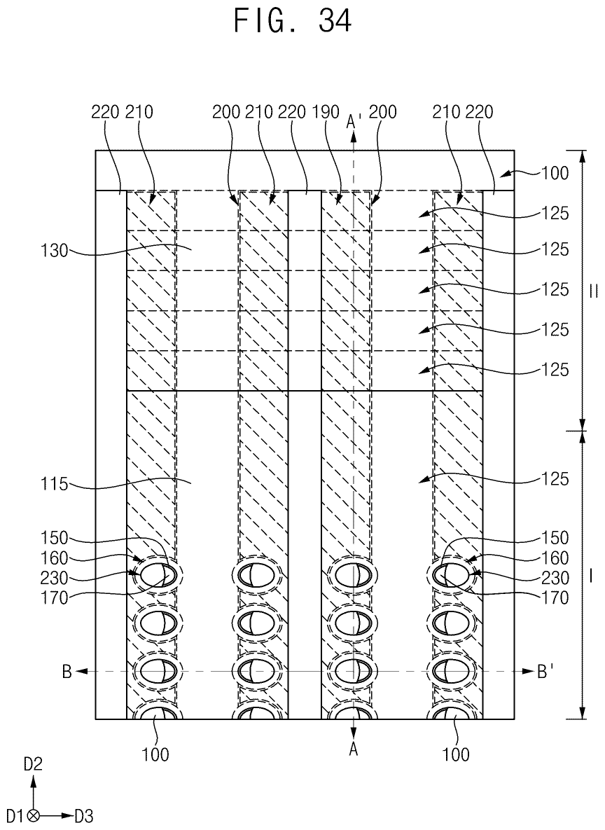

In FIGS. 34 to 36, a portion of the third insulation pattern 170 and a portion of the second insulation layer 150 adjacent thereto may be removed to form a second hole 230 exposing the upper surface of the substrate 100. As the second hole 230 is formed, sidewalls of the channel 160 and the first insulation pattern 115 may partially exposed.

In some example embodiments, a plurality of second holes 230 may be spaced apart from each other in the second direction D2 and the third direction D3 on the first region I of the substrate 100.

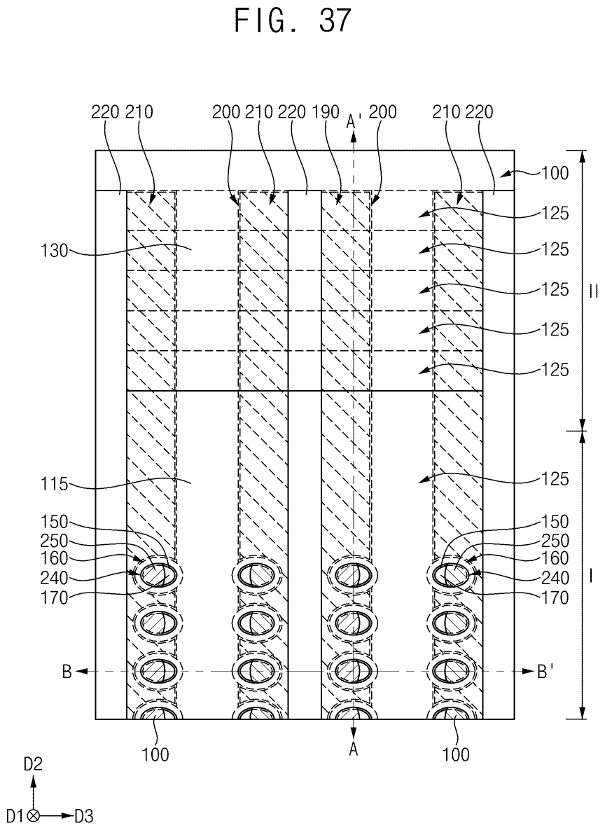

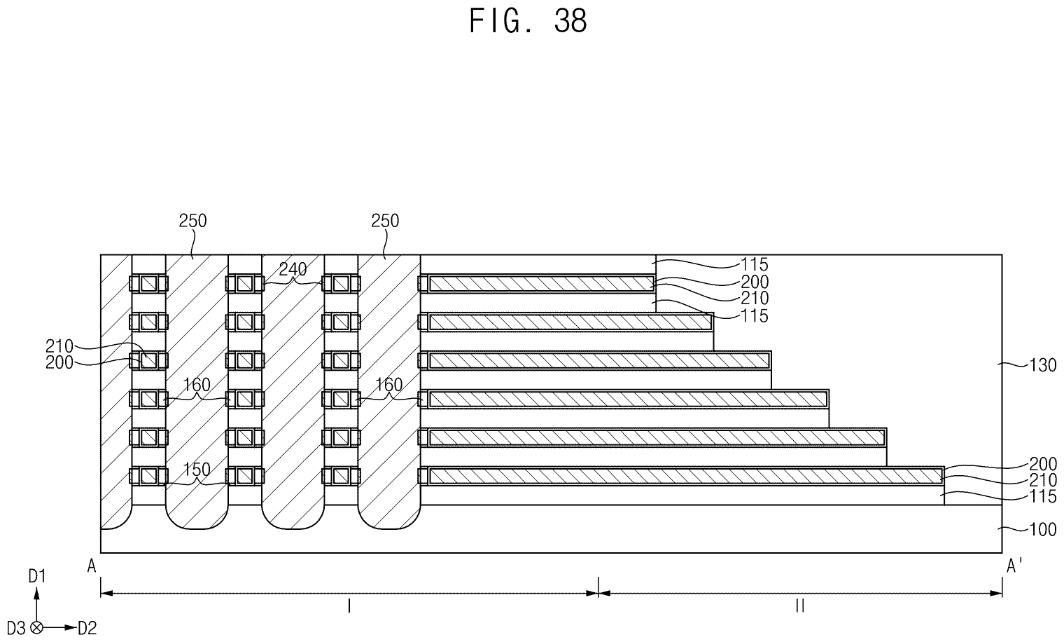

In FIGS. 37 to 39, a first ohmic contact pattern 240 may be formed on the sidewall of the channel 160 exposed by the second hole 230.

In some example embodiments, the first ohmic contact pattern 240 may be formed by forming a first metal layer on an inner wall of the second hole 230, the upper surfaces of the third and fourth insulation patterns 170 and 220, the upper surface of the second insulation layer 150, the upper surface of the mold and the upper surface of the first insulating interlayer 130, and performing a heat treatment process on the first metal layer so that a metal included in the first metal layer and a semiconductor material included in the channel 160 may be reacted with each other, and an unreacted portion of the first metal layer may be removed.

A plurality of first ohmic contact patterns 240 may be spaced apart from each other in the first direction D1 on the first region I of the substrate 100, and may also be spaced apart from each other in the second direction D2 and the third direction D3. Each of the first ohmic contact patterns 240 may have a shape of, e.g., a portion of a ring.

The first ohmic contact 240 may also be formed on the upper surface of the substrate 100 including a semiconductor material and exposed by the second hole 230.

A bitline layer may be formed on the substrate 100, the third insulation pattern 170 and the fourth insulation pattern 220, the second insulation layer 150, the mold and the first insulating interlayer 130 to fill the second hole 230, and a planarization process may be performed on the bitline layer until the upper surface of the first insulating interlayer 130 is exposed to form a bitline 250 in the second hole 230.

In some example embodiments, a plurality of bitlines 250 may be spaced apart from each other in the second direction D2 and the third direction D3 on the first region I of the substrate 100, and each of the bitlines 250 may have a shape of a pillar extending in the first direction D1. Each of the bitlines 250 may contact the first ohmic contact pattern 240, and may be electrically connected to the channels 160 disposed in the first direction D1 through the first ohmic contact pattern 240.

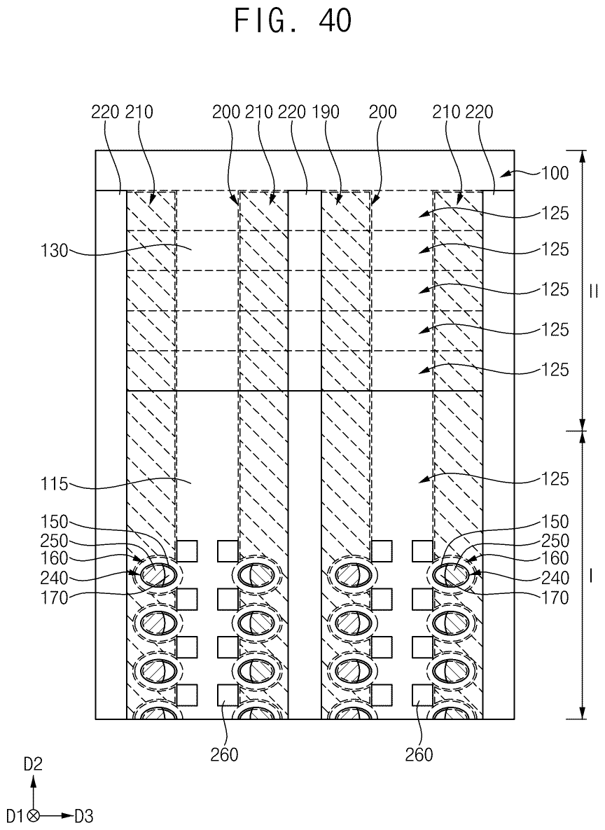

In FIG. 40, a third hole may be formed through the mold to expose the upper surface of the substrate 100 on the first region I of the substrate 100, and a fifth insulation pattern 260 may be formed in the third hole. The third hole may also extend through an upper portion of the substrate 100, and the fifth insulation pattern 260 in the third hole may extend through the upper portion of the substrate 100. In some example embodiments, the fifth insulation pattern 260 may have a pillar shape extending in the first direction D1, and a plurality of fifth insulation patterns 260 may be spaced apart from each other in the second direction D2 and the third direction D3 to form a fifth insulation pattern array.

The fifth insulation pattern array may include a plurality of fifth insulation pattern columns, each of which may include a plurality of fifth insulation patterns 260 disposed in the second direction D2, spaced apart from each other in the third direction D3. Each of the fifth insulation patterns 260 included in each of the fifth insulation pattern columns may extend through a portion of the mold between ones of the channels 160 of a corresponding one of the channel columns, and may contact a sidewall of the first gate insulation layer 200. Ones of the fifth insulation patterns 260 included in respective ones of the fifth insulation pattern columns neighboring in the third direction D3 may be aligned with each other in the third direction D3.

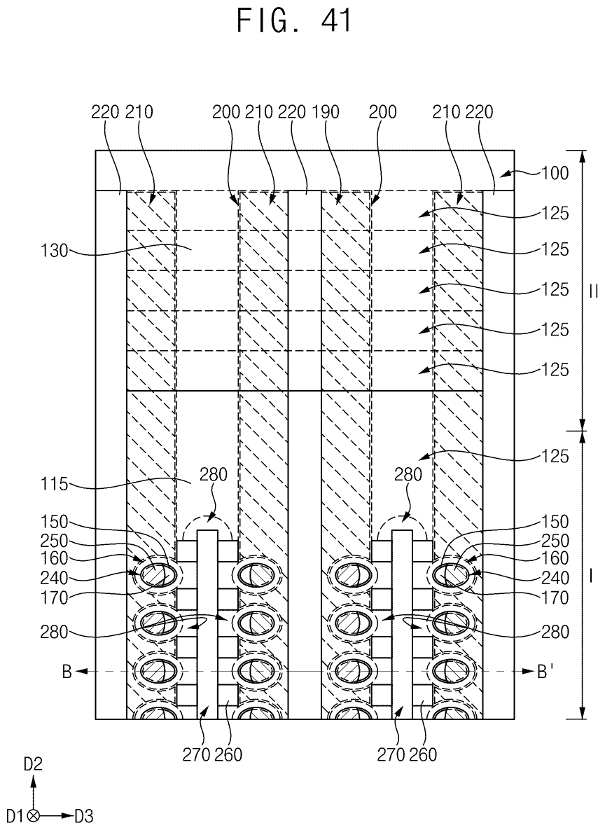

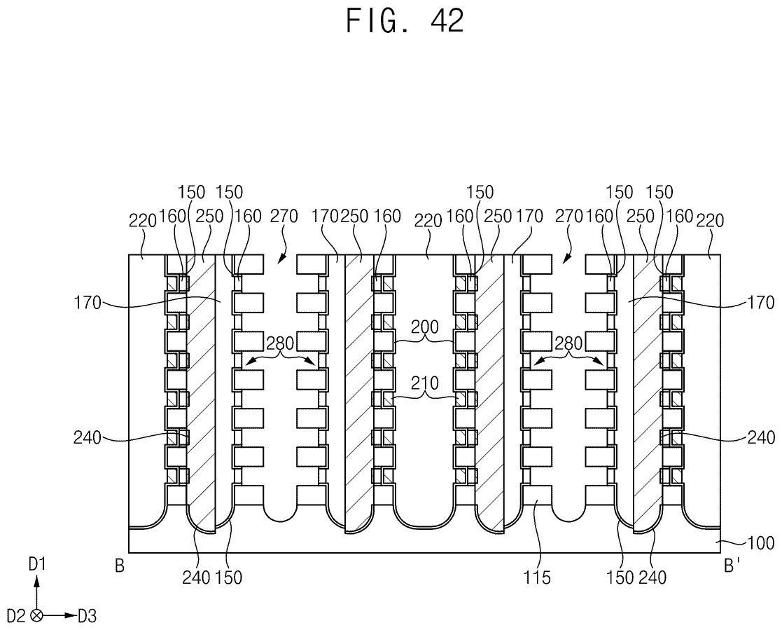

In FIGS. 41 and 42, a second opening 270 may be formed through the mold to expose the upper surface of the substrate 100 on the first region I of the substrate 100, and a portion of the first sacrificial pattern 125 exposed by the second opening 270 and a portion of the second insulation layer 150 adjacent thereto may be removed by, e.g., a wet etching process to form a third recess 280.

In some example embodiments, the second opening 270 may extend in the second direction D2 between neighboring ones of the fifth insulation pattern columns in the third direction D3, and may expose sidewalls of the fifth insulation patterns 260 included in the neighboring ones of the fifth insulation pattern columns. In some example embodiments, a plurality of third recesses 280 may be spaced apart from each other in the second direction D2 by the fifth insulation patterns 260, and may also be spaced apart from each other in the first direction D1 by the first insulation patterns 115. Each of the third recesses 280 may expose a sidewall, particularly, a sidewall in the third direction D3 of a corresponding one of the channels 160.

During the wet etching process, a portion of the first sacrificial pattern 125 at each of end portions in the second direction D2 of the second opening 270 may also be removed, and, in a plan view, the third recess 280 may have a shape of a semi-circle adjacent to each of the end portions of the second opening 270.

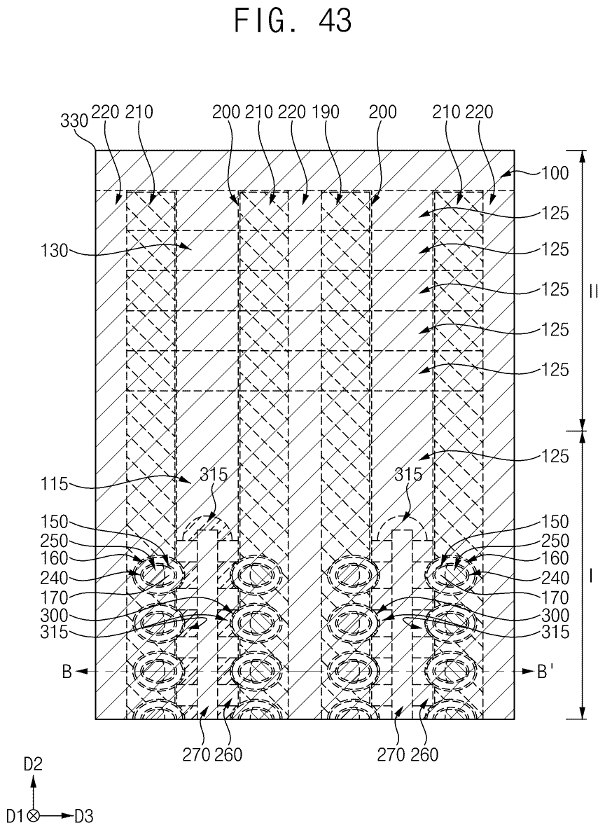

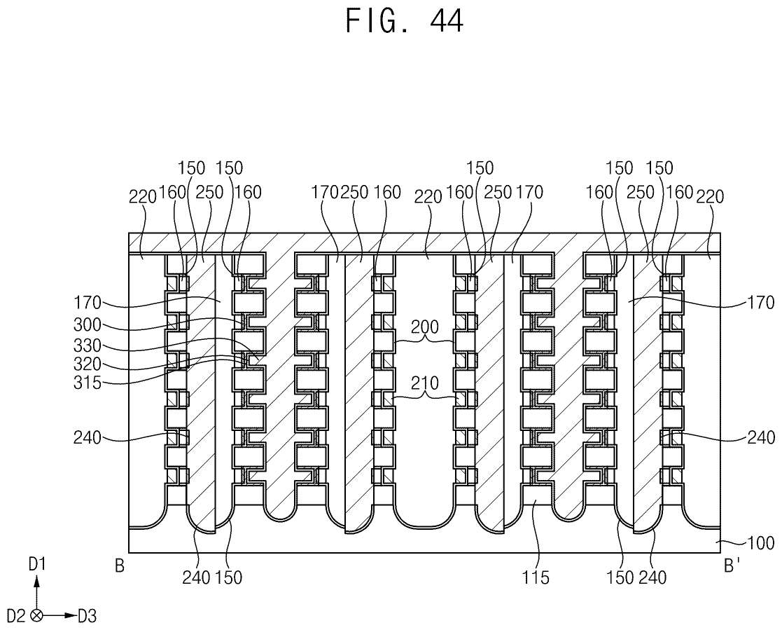

In FIGS. 43 and 44, a second ohmic contact pattern 300 may be formed on the sidewall of the channel 160 exposed by the third recess 280. In some example embodiments, the second ohmic contact pattern 300 may be formed by forming a second metal layer on inner walls of the second opening 270 and the third recess 280, the upper surfaces of the third insulation pattern 170 and the fourth insulation pattern 220, the upper surface of the second insulation layer 150, an upper surface of the bitline 250, the upper surface of the mold and the upper surface of the first insulating interlayer 130, and performing a heat treatment process on the second metal layer so that a metal included in the second metal layer and the semiconductor material included in the channel 160 may be reacted with each other, and an unreacted portion of the second metal layer may be removed.

A plurality of second ohmic contact patterns 300 may be spaced apart from each other in the first direction D1 on the first region I of the substrate 100, and may also be spaced apart from each other in the second direction D2 and the third direction D3. Each of the second ohmic contact patterns 240 may have a shape of, e.g., a portion of a ring. The second ohmic contact 300 may also be formed on the upper surface of the substrate 100 including the semiconductor material and exposed by the second opening 270.

A first capacitor electrode layer may be formed on the inner walls of the second opening 270 and the third recess 280, the upper surfaces of the third insulation pattern 170 and the fourth insulation pattern 220, the upper surface of the second insulation layer 150, the upper surface of the bitline 250, the upper surface of the mold and the upper surface of the first insulating interlayer 130, forming a second sacrificial layer on the first capacitor electrode layer to fill the third recess 280, and performing, e.g., a wet etching process on the second sacrificial layer to form a second sacrificial pattern in the third recess 280, and a portion of the first capacitor electrode layer at an outside of the third recess 280 may be exposed.

The exposed portion of the first capacitor electrode layer may be removed to form a first capacitor electrode 315 on the inner wall of the third recess 280, and the second sacrificial pattern may be removed. In some example embodiments, a plurality of first capacitor electrodes 315 may be spaced apart from each other in the first direction D1 on the first region I of the substrate 100, and may also be spaced apart from each other in the second direction D2 and the third direction D3 to form a first capacitor electrode array. The first capacitor electrode array may include a plurality of first capacitor electrode columns, each of which may include the first capacitor electrodes 315 spaced apart from each other in the second direction D2, spaced apart from each other in the third direction D3.

Each of the first capacitor electrodes 315 may contact sidewalls of the second ohmic contact pattern 300 and the second insulation layer 150, and may be electrically connected to the channel 160 through the second ohmic contact pattern 300. The first capacitor electrode 315 may also be formed in the third recess 280 adjacent to each of end portions of the second opening 270 in the second direction D2, which may have a shape of, e.g., a semi-circle in a plan view.

A dielectric layer 320 may be formed on the inner wall of the second opening 270, the upper surfaces of the third insulation pattern 170 and the fourth insulation pattern 220, the upper surface of the second insulation layer 150, the upper surface of the bitline 250, the upper surface of the mold and the upper surface of the first insulating interlayer 130, and a second capacitor electrode layer 330 may be formed on the dielectric layer 320 to fill the second opening 270.

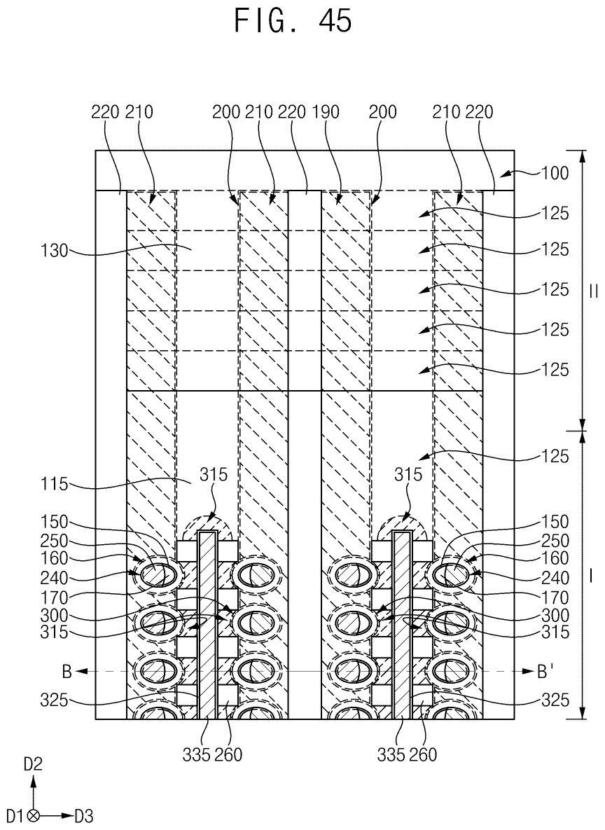

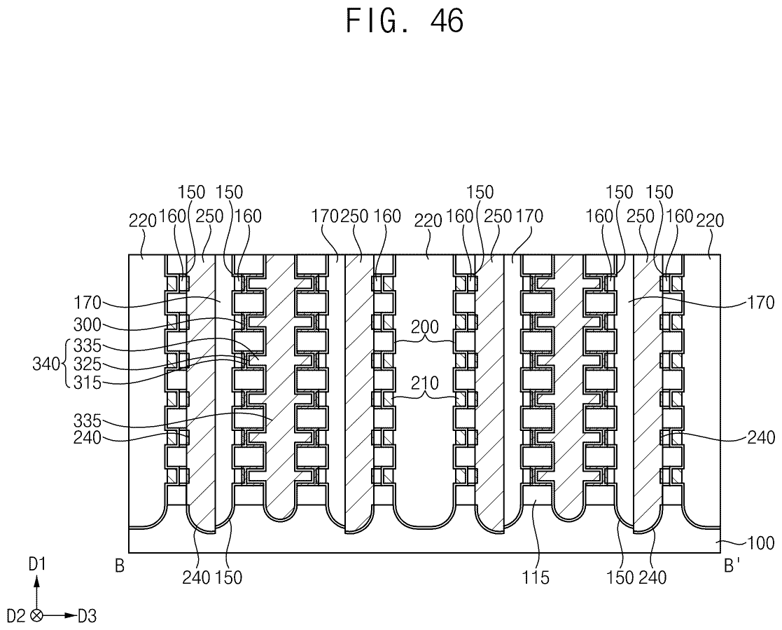

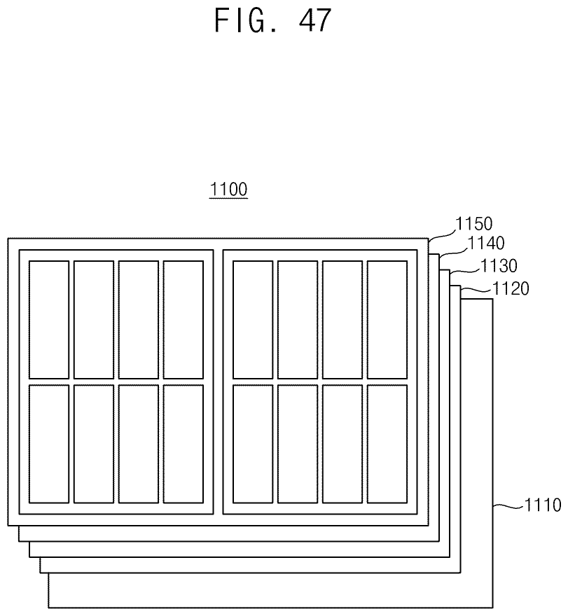

In FIGS. 45 and 46, a planarization process may be performed on the second capacitor electrode layer 330 and the dielectric layer 320 until the upper surface of the mold is exposed so that the second capacitor electrode layer 330 and the dielectric layer 320 may be transformed into a second capacitor electrode 335 and a dielectric pattern 325, respectively. The first capacitor electrode 315, the dielectric pattern 325, and the second capacitor electrode 335 may collectively form a capacitor structure 340.

In some example embodiments, the second capacitor electrode 335 may extend in the second direction D2 on the first region I of the substrate 100, and a plurality of second capacitor electrodes 335 may be spaced apart from each other in the third direction D3. The second capacitor electrode 335 may include an extension portion extending in the second direction D2 and a first protrusion portion protruding in the third direction D3 from each of opposite sidewalls in the third direction D3 of the extension portion and facing the sidewall of the channel 160. In some example embodiments, the second capacitor electrode 335 may include a plurality of first protrusion portions spaced apart from each other in the second direction D2 and the third direction D3, and may also be spaced apart from each other in the first direction D1. The second capacitor electrode 335 may further include a second protrusion portion protruding from each of end portions in the second direction D2 of the extension portion and having a shape of a semi-circle in a plan view.

Referring back to FIGS. 16 to 18, a second insulating interlayer 370 may be formed on the third insulation pattern 170, the fourth insulation pattern 220, and the fifth insulation pattern 260, the dielectric pattern 325, the second capacitor electrode 335, the second insulation layer 150, the bitline 250, the mold and the first insulating interlayer 130, and a first contact plug 380 extending through the first insulating interlayer 130 and the second insulating interlayer 370 to contact a pad of a corresponding one of the first gate electrodes 210 and a second contact plug extending through the second insulating interlayer 370 to contact the upper surface of a corresponding one of the bitlines 250 may be formed. A third contact plug may also be formed through the second insulating interlayer 370 to contact an upper surface of a corresponding one of the second capacitor electrodes 335.

By the above processes, a semiconductor memory device may be manufactured.

As illustrated above, the mold including the first insulation layer 110 and the first sacrificial layer 120 may be formed on the substrate 100, the first hole 140 may be formed through the mold, the portion of the first sacrificial layer 120 adjacent to the first hole 140 may be removed to form the first recess 145, and the channel 160 may be formed in the first recess 145. The third insulation pattern 170 may be formed in the first hole 140, the first opening 180 may be formed through the mold, and the portion of the first sacrificial layer 120 adjacent to the first opening 180 may be removed to form the second recess 190, and the first gate electrode 210 may be formed in the second recess 190.

The third insulation pattern 170 may be partially removed to form the second hole 230, the bitline 250 may be formed in the second hole 230, the second opening 270 may be formed through the mold, the portion of the first sacrificial layer 120 adjacent to the second opening 270 may be removed to form the third recess 280 exposing the sidewall of the channel 160, and the first capacitor electrode 315 may be formed in the third recess 280.

Accordingly, the channel 160, the first gate electrode 210, and the first capacitor electrode 315 may be formed at the same level, so that the vertical thickness thereof may be reduced. Accordingly, the formation of the channel 160, the first gate electrode 210, and the first capacitor electrode 315 may be easily performed.

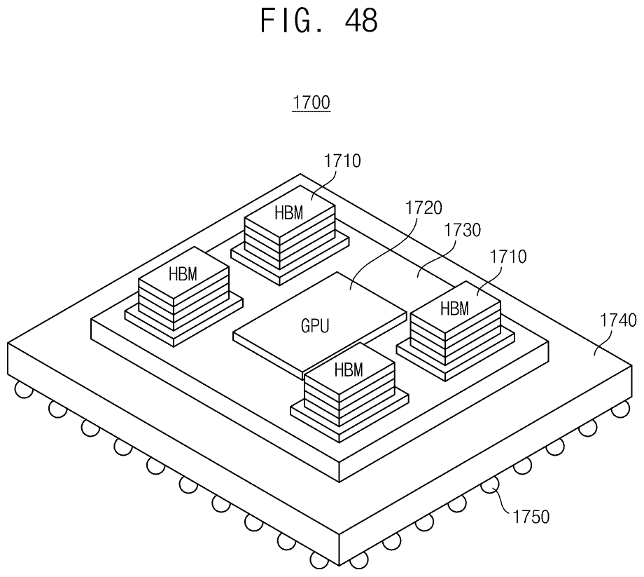

FIG. 47 is a diagram illustrating a semiconductor memory device according to some example embodiments.

An example structure of a high bandwidth memory is illustrated in FIG. 47. Referring to FIG. 47, a high bandwidth memory (HBM) 1100 may include a structure stacked with a plurality of DRAM semiconductor dies 1120, 1130, 1140 and 1150.

The high bandwidth memory may be optimized for high bandwidth operation of the stacked structure through a plurality of independent interfaces, referred to as channels. Depending on the HBM standard, each DRAM stack may support up to eight channels.

FIG. 47 illustrates an example where four DRAM semiconductor dies are stacked. Each semiconductor die may provide additional capacity and additional channels in the stacked structure. Each channel provides access to an independent set of DRAM banks. A request from one channel does not access data attached to another channel. The channels are independently clocked and do not need to be synchronized with each other.

The high bandwidth memory 1100 may optionally include a buffer die or interface die 1110 that is located at the bottom of the stack structure and provides signal redistribution and other functions. Functions typically implemented in DRAM semiconductor dies 1120, 1130, 1140, 1150 may be implemented in such interface die 1110.

According to some example embodiments, at least one of the DRAM semiconductor dies 1120, 1130, 1140 and 1150 may include a shielding structure as described above. The shielding structure may be utilized to reduce electrical interference between the global bitlines and the memory cell array, resulting in improved performance.

FIG. 48 is a diagram illustrating a semiconductor package including semiconductor memory devices according to some example embodiments.

Referring to FIG. 48, a semiconductor package 1700 may include one or more stacked memory devices 1710 and a GPU 1720. The stacked memory devices 1710 and GPU 1720 may be mounted on an interposer 1730, and the interposer 1730 with the stacked memory devices 1710 and GPU 1720 may be mounted on a package substrate 1740. GPU 1720 may perform substantially the same functions as the memory controller described above or may include a memory controller internally. The GPU 1720 may store data generated or utilized during graphics processing in one or more stacked memory devices 1710.

The stacked memory devices 1710 may be implemented in various forms, and in some example embodiments, the stacked memory devices 1710 may be high bandwidth memory (HBM) type memory devices with multiple layers stacked on top of each other. Accordingly, the stackable memory device 1710 may include a buffer die and a plurality of memory dies.

According to some example embodiments, the stacked memory device 1710 may include a shielding structure as described above. The shielding structure may be utilized to reduce electrical interference between the global bitlines and the memory cell array for improved performance.

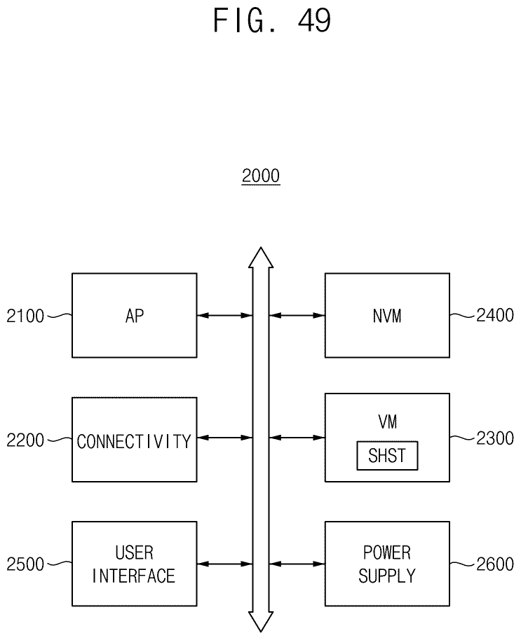

FIG. 49 is a block diagram illustrating a mobile system including a semiconductor memory device according to some example embodiments.

Referring to FIG. 49, a mobile system 2000 includes an application processor 2100, a connectivity portion 2200, a semiconductor memory device 2300, a non-volatile semiconductor memory device 2400, a user interface 2500, and a power supply 2600. According to some example embodiments, the mobile system 2000 may be or include, or be included in, any mobile system, such as one or more of a Mobile Phone, Smart Phone, Personal Digital Assistant (PDA), Portable Multimedia Player (PMP), Digital Camera, Music Player, Portable Game Console, Navigation system, etc.

The application processor 2100 may run applications that provide internet browsers, games, videos, and the like. The communication section 2200 may perform wireless or wired communication with external devices.

The semiconductor memory device 2300 may store data processed by the application processor 2100, or may act as working memory.

The non-volatile semiconductor memory device 2400 may store a boot image for booting the mobile system 2000. The user interface 2500 may include one or more input devices, such as a keypad, a touch screen, and/or one or more output devices, such as a speaker, a display device.

The power supply 2600 may provide an operating voltage for the mobile system 1200.

According to some example embodiments, the semiconductor memory device 2300 may include a shielding structure SHST as described above. The shielding structure SHST may be utilized to reduce electrical interference between the global bitlines and the memory cell array for improved performance.

As described above, the semiconductor memory device according to some example embodiments may have improved performance by reducing electrical interference between the global bitlines and the memory cell array using the shielding structure. Shielding between the global bitlines and the capacitor electrode of the memory cell using the shielding structure may improve the electrical performance of the semiconductor memory device by reducing the coupling between the global bitlines and the capacitor electrode and/or by increasing the capacitance of the capacitor electrode to stabilize the voltage of the capacitor electrode.

Inventive concepts may be applied to a semiconductor memory device and any electronic devices and systems including the semiconductor memory device. For example, inventive concepts may be applied to systems such as one or more of a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, etc.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

The foregoing is illustrative of example embodiments and is not to be construed as limiting thereof. Although a few example embodiments have been described, those skilled in the art will readily appreciate that many modifications are possible in the example embodiments without materially departing from inventive concepts. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a memory cell array including a plurality of memory cells on a semiconductor substrate;
a plurality of global bitlines above the memory cell array in a first direction perpendicular to a top surface of the semiconductor substrate, arranged in a second direction parallel to a top surface of the semiconductor substrate, and extending in a third direction parallel to a top surface of the semiconductor substrate;
a plurality of local bitlines extending in the first direction and connecting the plurality of memory cells and the plurality of global bitlines; and
a shielding structure between the memory cell array and the plurality of global bitlines, the shielding structure configured to at least partly shield electrical interference between the memory cell array and the plurality of global bitlines.

2. The semiconductor memory device of claim 1, wherein the shielding structure includes:
a shielding conductive plate parallel to the top surface of the semiconductor die to cover the memory cell array.

3. The semiconductor memory device of claim 2, wherein
the shielding conductive plate defines a plurality of apertures, and
the plurality of local bitlines are connected to the plurality of global bitlines by passing through the plurality of apertures and extending in the first direction such that the plurality of local bitlines do not contact the shielding conductive plate.

4. The semiconductor memory device of claim 1, wherein the semiconductor device is configured to have a first voltage commonly applied to the plurality of memory cells and to the shielding structure.

5. The semiconductor memory device of claim 1, wherein the semiconductor device is configured to have a second voltage applied to the shielding structure, the second voltage independent of a first voltage commonly applied to the plurality of memory cells.

6. The semiconductor memory device of claim 1, further comprising:
a first switch configured to apply a first voltage commonly applied to the plurality of memory cells to the shielding structure in response to a first switch signal; and
a second switch configured to apply a second voltage independent of the first voltage to the shielding structure in response to a second switch signal.

7. The semiconductor memory device of claim 6, further comprising:
a mode register configured to store control values associated with controlling operation of the semiconductor memory device,
wherein the semiconductor device is configured to selectively activate one of the first switch signal and the second switch signal based on a value stored in the mode register.

8. The semiconductor memory device of claim 1, wherein the shielding structure includes:
a plurality of shielding conductive stripes parallel to the top surface of the semiconductor die, extending in the second direction, and arranged in the third direction to cover portions of the memory cell array that are not traversed by the plurality of local bitlines.

9. The semiconductor memory device of claim 8, wherein the plurality of local bitlines are connected to the plurality of global bitlines by passing between the plurality of shielding conductive stripes and extending in the first direction such that the plurality of local bitlines do not contact the plurality of shielding conductive stripes.

10. The semiconductor memory device of claim 1, wherein
the plurality of memory cells are arranged in a plurality of cell layers spaced apart and stacked in the first direction,
memory cells in each cell layer of the plurality of cell layers are arranged in the second direction and the third direction, and
the plurality of local bitlines are arranged in the second direction and the third direction.

11. The semiconductor memory device of claim 10, wherein
the shielding structure includes a shielding conductive plate parallel to the top surface of the semiconductor die to cover the memory cell array,
the shielding conductive plate defines a plurality of apertures arranged in the second direction and the third direction, and
the plurality of local bitlines are connected to the plurality of global bitlines by passing through the plurality of apertures and extending in the first direction such that the plurality of local bitlines do not contact the shielding conductive plate.

12. The semiconductor memory device of claim 10, wherein each local bitline of the plurality of local bitlines is connected to one memory cell included in each cell layer of the plurality of cell layers.

13. The semiconductor memory device of claim 10, wherein each local bitline of the plurality of local bitlines is connected to two memory cells included in each cell layer of the plurality of cell layers.

14. The semiconductor memory device of claim 1, wherein the plurality of memory cells are dynamic random access memory (DRAM) cells such that each memory cell includes one cell transistor and one cell capacitor.

15. A semiconductor memory device comprising:
a first semiconductor die; and
a second semiconductor die stacked on the first semiconductor die in a first direction perpendicular to a semiconductor substrate of the first semiconductor die,
wherein the first semiconductor die includes,
a memory cell array including a plurality of memory cells on the semiconductor substrate,
a plurality of global bitlines above the memory cell array in a first direction perpendicular to a top surface of the semiconductor substrate, arranged in a second direction parallel to a top surface of the semiconductor substrate, and extending in a third direction parallel to a top surface of the semiconductor substrate,
a plurality of local bitlines extending in the first direction and connecting the plurality of memory cells and the plurality of global bitlines, and
a shielding structure between the memory cell array and the plurality of global bitlines, the shielding structure configured to at least partly shield electrical interference between the memory cell array and the plurality of global bitlines, and
wherein the second semiconductor die includes,
a sense amplifier circuit configured to sense data stored in select memory cells among the plurality of memory cells based on voltages of the plurality of global bitlines.

16. The semiconductor memory device of claim 15, wherein the shielding structure includes:
a shielding conductive plate parallel to the top surface of the semiconductor die to cover the memory cell array.

17. The semiconductor memory device of claim 16, wherein
the shielding conductive plate defines a plurality of apertures, and
wherein the plurality of local bitlines are connected to the plurality of global bitlines by passing through the plurality of apertures and extending in the first direction such that the plurality of local bitlines do not contact the shielding conductive plate.

18. The semiconductor memory device of claim 15, further comprising:
a first switch configured to apply a first voltage commonly applied to the plurality of memory cells to the shielding structure in response to a first switch signal; and
a second switch configured to apply a second voltage independent of the first voltage to the shielding structure in response to a second switch signal.

19. The semiconductor memory device of claim 18, further comprising:
a mode register configured to store control values associated with controlling operation of the semiconductor memory device,
wherein the semiconductor memory device is configured to selectively activate one of the first switch signal and the second switch signal based on a value stored in the mode register.

20. A semiconductor memory device comprising:
a memory cell array including a plurality of dynamic random access memory (DRAM) cells memory cells on a semiconductor substrate, wherein the plurality of DRAM cells are arranged in a plurality of cell layers spaced apart and stacked in a first direction perpendicular to a top surface of the semiconductor substrate, and DRAM cells in each cell layer of the plurality of cell layers are arranged in a second direction and a third direction;
a plurality of global bitlines above the memory cell array in the first direction, arranged in a second direction parallel to a top surface of the semiconductor substrate, and extending in a third direction parallel to a top surface of the semiconductor substrate;
a plurality of local bitlines extending in the first direction, arranged in the second direction and the third direction, and connecting the plurality of memory cells and the plurality of global bitlines; and
a shielding conductive plate between the memory cell array and the plurality of global bitlines, the shielding conductive plate configured to at least partly shield electrical interference between the memory cell array and the plurality of global bitlines, wherein the shielding conductive plate is parallel to the top surface of the semiconductor die to cover the memory cell array.
